(19) United States
(12) Patent Application Publication
(10) Pub. No.: US 2026/0150536 A1
(43) Pub. Date: May 28, 2026

(54) DISPLAY DEVICE

(71) Applicant: LG Display Co., Ltd., Seoul (KR)

(72) Inventors: JaeHee PARK, Paju-si (KR); DongYoon KIM, Paju-si (KR); Taehee KO, Paju-si (KR)

(73) Assignee: LG Display Co., Ltd., Seoul (KR)

(21) Appl. No.: 19/343,844

(22) Filed: Sep. 29, 2025

(30) Foreign Application Priority Data
Nov. 26, 2024 (KR) 10-2024-0170286

(51) Int. Cl. H10K 59/131; H10K 59/124

(52) U.S. Cl. CPC H10K 59/131; H10K 59/124

(57) ABSTRACT

A display device is provided that includes a substrate, a gate line arranged in a first direction on the substrate, and at least one line arranged in a second direction different from the first direction so as to cross the gate line. An active line is disposed between the gate line and the at least one line, and overlaps both the gate line and the at least one line. The active line extends in a same direction as the gate line and is electrically connected to the gate line through a contact hole. This arrangement allows for the prevention and repair of short defects that may occur between the gate line and the at least one line, for example, due to particles present in an insulating layer during manufacturing, by enabling selective disconnection of the active line without damaging the primary signal lines.

### CROSS-REFERENCE TO RELATED APPLICATIONS

This application claims the benefit of the Republic of Korea Patent Application No. 10-2024-0170286 filed on November 26, 2024, each of which is hereby incorporated by reference in its entirety.

### BACKGROUND

### Technical Field

The present disclosure relates to a display device.

### Description of Related Art

A display device includes a plurality of signal lines and a plurality of thin film transistors connected to the plurality of signal lines. The signal lines may include, for example, gate lines for transmitting gate signals, data lines for transmitting image data, and power lines for supplying driving power. The thin film transistors operate in response to the signals supplied through the signal lines to control the flow of current to corresponding light emitting elements. In high resolution display devices, these lines are arranged in multiple layers to achieve a compact layout that accommodates the large number of connections required for fine pixel control.

In such multilayer configurations, certain signal lines are positioned above or below others with an insulating layer disposed between them. This arrangement allows the lines to cross without direct electrical contact, enabling a denser circuit layout while maintaining electrical isolation. The insulating layer may be formed of an inorganic material such as silicon nitride or silicon oxide, or an organic insulating material, depending on the required electrical and mechanical characteristics.

### BRIEF SUMMARY

However, during the manufacturing process of the display device, unwanted particles can be generated at various stages, such as during thin film deposition, photolithography, or etching. These particles may become embedded within the insulating layer or trapped at the interface between conductive and insulating layers. When such particles are present between overlapping signal lines, they can form unintended conductive paths or reduce the dielectric strength of the insulating layer.

As a result, a short defect may occur between signal lines that are intended to remain electrically isolated. For example, particles trapped between a gate line and an overlapping data line can cause these lines to be electrically connected, leading to malfunction of the associated thin film transistors and deterioration of display quality. In severe cases, the short defect may disable an entire pixel or group of pixels, thereby reducing manufacturing yield and reliability.

The present disclosure has been made in view of the above problems and it is an aspect of the present disclosure to provide a display device capable of preventing a short defect problem between a plurality of signal lines due to particles occurring during a manufacturing process.

For example, the specification describes a display device architecture that incorporates sacrificial active lines AL1 and AL2 positioned beneath the gate line GL and the sensing control line SCL, respectively, and connected through strategically placed contact holes. These active lines completely overlap underlying signal lines such as VDDL, data lines, and reference lines, and are wider than the lines they cross. This arrangement ensures that any particle induced short occurs through the active line rather than through the main functional lines. Defects can be repaired by cutting the active line with a laser from the underside of the substrate at defined locations between contact holes, thereby isolating the short without damaging the main line. This approach provides a predictable and non-destructive repair method not available in conventional stacked line layouts.

Additional aspects include gate line extension parts GL_EP1 to GL_EP4 that route signals to adjacent sub-pixels in directions different from the main gate line and are arranged to face each other across the reference line without connecting. This configuration improves aperture ratio, sharpness, and transparency while reducing routing congestion. In certain embodiments, the first pixel electrode is divided into two independently drivable sub-electrodes connected through separate connection electrodes. This structure allows a defective portion to be isolated so that partially defective pixels can be retained, thereby improving overall manufacturing yield.

The design also employs a light blocking layer LS formed in the same process step as certain signal lines. This layer overlaps the active layers to block stray light and also serves as one electrode of a capacitor. The dual purpose of this layer reduces process complexity and enhances the stability of the thin film transistors. The pixel structure supports both top and bottom emission configurations by controlling the overlap between line areas and light emitting areas, which enables flexibility across different display products without altering the core routing arrangement.

In accordance with an aspect of the present disclosure, the above and other technical effects can be accomplished by the provision of a display device comprising a substrate, a gate line arranged in a first direction on the substrate, at least one line arranged in a second direction different from the first direction to cross the gate line on the substrate, and an active line disposed between the gate line and the at least one line and overlapping the gate line and the at least one line, respectively, wherein the active line extends in a same direction as the gate line, and is connected to the gate line through a contact hole.

In addition, in accordance with an aspect of the present disclosure, the above and other technical effects can be accomplished by the provision of a display device comprising a substrate, a gate line arranged in a first direction on the substrate, a gate line extension part including at least a portion extending in a direction different from the first direction in the gate line, a first data line, a second data line, a third data line, a fourth data line, a reference line, and a power line arranged in a second direction different from the first direction to cross the gate line on the substrate, and an active line crossing the first data line, the second data line, the third data line, the fourth data line, the reference line, and the power line and extending in the same direction as the gate line, wherein the active line overlaps the gate line and is connected to the gate line through a contact hole

It is to be understood that both the foregoing general description and the following detailed description are exemplary and explanatory and are intended to provide further explanation of the inventive concepts as claimed

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description explain the principle of the disclosure. In the drawings:

FIG. 1 is a circuit diagram of an electroluminescent display device according to an embodiment of the present disclosure.

FIG. 2 is a plan view of an electroluminescent display device according to an embodiment of the present disclosure.

FIG. 3 is a cross-sectional view of an electroluminescent display device according to an embodiment of the present disclosure, which corresponds to a cross-section taken along line A-A of FIG. 2.

FIG. 4 is a cross-sectional view of an electroluminescent display device according to an embodiment of the present disclosure, which corresponds to a cross-section taken along line B-B of FIG. 2.

FIG. 5 is a cross-sectional view of an electroluminescent display device according to an embodiment of the present disclosure, which is a view showing a method of repairing a short defect caused by particles in FIG. 4.

FIG. 6 is a cross-sectional view of an electroluminescent display device according to an embodiment of the present disclosure, which corresponds to a cross section taken along line C-C of FIG. 2.

FIG. 7 is a plan view of an electroluminescent display device according to another embodiment of the present disclosure.

FIG. 8 is a cross-sectional view of an electroluminescent display device according to another embodiment of the present disclosure, which corresponds to a cross-section taken along line A-A of FIG. 7.

FIG. 9 is a cross-sectional view of an electroluminescent display device according to another embodiment of the present disclosure, which corresponds to a cross-section taken along line B-B of FIG. 7.

FIG. 10 is a cross-sectional view of an electroluminescent display device according to another embodiment of the present disclosure, which is a view showing a method of repairing a short defect caused by particles in FIG. 9.

FIG. 11 is a plan view of an electroluminescent display device according to another embodiment of the present disclosure.

FIG. 12 is a cross-sectional view of an electroluminescent display device according to another embodiment of the present disclosure, which corresponds to a cross-section taken along line A-A of FIG. 11.

FIG. 13 is a cross-sectional view of an electroluminescent display device according to another embodiment of the present disclosure, which corresponds to a cross-section taken along line B-B of FIG. 11.

FIG. 14 is a cross-sectional view of an electroluminescent display device according to another embodiment of the present disclosure, which corresponds to a cross section taken along line C-C of FIG. 11.

FIG. 15 is a cross-sectional view of an electroluminescent display device according to another embodiment of the present disclosure, which corresponds to a cross section taken along line C-C of FIG. 11.

Throughout the drawings and the detailed description, unless otherwise described, the same drawing reference numerals should be understood to refer to the same elements, features, and structures.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification. In the following description, when the detailed description of the relevant known function or configuration is determined to unnecessarily obscure the important point of the present disclosure, the detailed description will be omitted. In a case where ‘comprise,’ ‘have’ and ‘include’ described in the present disclosure are used, another portion may be added unless ‘only~’ is used. The terms of a singular form may include plural forms unless referred to the contrary.

In interpreting the components, it is interpreted as including the error range even if there is no separate explicit description of the error range.

In describing a position relationship, for example, when the position relationship is described as ‘upon~,’ ‘above~,’ ‘below~’ and ‘next to~,’ one or more portions may be disposed between two other portions unless ‘just’ or ‘direct’ is used. The terms, such as “below,” “lower,” “above,” “upper” and the like, may be used herein to describe a relationship between element(s)as illustrated in the drawings. It will be understood that the terms are spatially relative and based on the orientation depicted in the drawings.

A description of a time relationship may include a case in which the temporal precedence relationship is described as “after,” “following,” or “before,” etc., and is not continuous unless “right away” or “directly,” is used.

Although the first, second, and the like are used to describe various components, these components are not limited by these terms. These terms are used only to distinguish one component from another. Therefore, a first component mentioned below may be a second component within a technical idea of a present disclosure.

It will be understood that, although the terms “first,” “second,” “A,” “B,” “(a),” and “(b),” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

If a component is stated to be “connected,” “coupled,” “connected,” or “attached” to another component, that component may be connected, coupled, connected, or attached directly to that other component, but it should be understood that other components may be interposed between each component that may be connected, coupled, connected, or attached indirectly, without any specific description.

It should be understood that if a component or layer is stated to be “in contact” or “overlapping” with another component or layer, the component or layer may be in direct contact or overlapping with another component or layer, but other components may be interposed between each component that may be indirectly in contact or overlapping without particular explicit description.

To further elaborate, as used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The term "coupled" and "in contact" should be interpreted in the same manner.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

“First direction,” “second direction,” “third direction,” “X-axis direction,” “Y-axis direction,” and “Z-axis direction” should not be interpreted only as a geometric relationship perpendicular to each other, but may mean that the configuration of the present disclosure has a wider direction within a range in which the configuration of the present disclosure may functionally act.

Features of each of the various embodiments of the present specification may be partially or entirely coupled or combined with each other, technically various interworking and driving are possible, and each of the embodiments may be independently implemented with respect to each other or may be implemented together in a related relationship.

Hereinafter, one embodiment of the present disclosure will be described in detail with reference to the accompanying drawings.

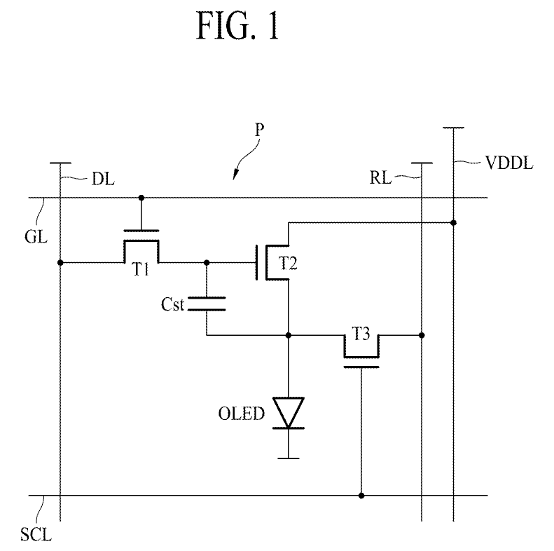

FIG. 1 is a circuit diagram of an electroluminescent display device according to an embodiment of the present disclosure.

As shown in FIG. 1, an electroluminescent display device according to an embodiment of the present disclosure includes a gate line GL, a sensing control line SCL, a high power line VDDL, a data line DL, a reference line RL, a switching thin film transistor T1, a driving thin film transistor T2, a sensing thin film transistor T3, a capacitor Cst, and an organic light emitting diode OLED.

The gate line GL supplies a gate signal to a gate terminal of the switching thin film transistor T1.

The sensing control line SCL supplies a sensing control signal to a gate terminal of the sensing thin film transistor T3. The sensing control line SCL may be omitted, and in this case, the gate terminal of the sensing thin film transistor T3 may be connected to the gate line GL to receive a sensing control signal from the gate line GL.

The high power line VDDL supplies high power to a drain terminal of the driving thin film transistor T2.

The data line DL supplies a data signal to a source terminal of the switching thin film transistor T1.

The reference line RL is connected to a drain terminal of the sensing thin film transistor T3.

The switching thin film transistor T1 is switched according to the gate signal supplied to the gate line GL to supply a data voltage supplied from the data line DL to the driving thin film transistor T2.

The driving thin film transistor T2 is switched according to the data voltage supplied from the switching thin film transistor T1 to generate a data current from the high power source supplied from the high power line VDDL and supplies the data current to the organic light emitting diode OLED.

The sensing thin film transistor T3 senses a threshold voltage deviation of the driving thin film transistor T2, which causes image quality to deteriorate. Such sensing of the threshold voltage deviation may be performed in a sensing mode. The sensing thin film transistor T3 supplies a voltage of the driving thin film transistor T2 to the reference line RL in response to the sensing control signal supplied from the sensing control line SCL.

The capacitor Cst maintains the data voltage supplied to the driving thin film transistor T2 for one frame, and is connected to a gate terminal and a source terminal of the driving thin film transistor T2, respectively.

The organic light emitting diode OLED emits predetermined light according to the data current supplied from the driving thin film transistor T2. The organic light emitting diode OLED includes an anode and a cathode, and a light emitting layer disposed between the anode and the cathode. The anode of the organic light emitting diode OLED is connected to the source terminal of the driving thin film transistor T2, and the cathode of the organic light emitting diode OLED is connected to a low power line. Although not shown, the low power line for supplying low power to the cathode of the organic light emitting diode OLED may be additionally disposed.

In the present disclosure, a power line means at least one of the high power line and the low power line.

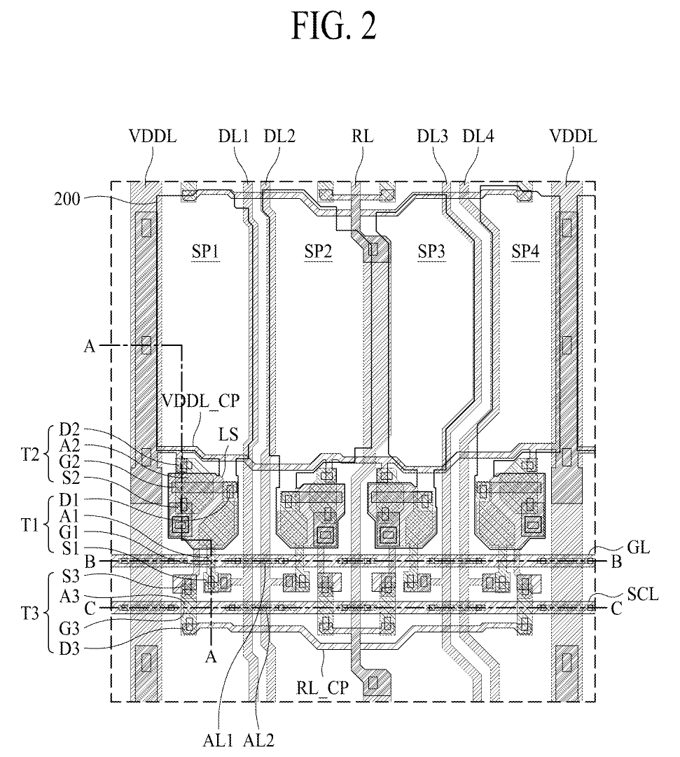

FIG. 2 is a plan view of an electroluminescent display device according to an embodiment of the present disclosure. In FIG. 2, a rectangular shape illustrates a contact hole disposed in the insulating layer so that two overlapping components with the insulating layer therebetween may be electrically connected to each other, which is the same in the following embodiment.

As shown in FIG. 2, a gate line GL and a sensing control line SCL are arranged in a first direction, for example, in a horizontal direction.

The gate line GL and the sensing control line SCL may be made of the same material on the same layer.

A plurality of first active lines AL1 are provided to overlap the gate line GL. The plurality of first active lines AL1 are spaced apart from each other while overlapping one gate line GL and extend in the same direction as the gate line GL. Each of the plurality of first active lines AL1 is connected to the gate line GL through a contact hole.

In addition, a plurality of second active lines AL2 are provided to overlap the sensing control line SCL. The plurality of second active lines AL2 are spaced apart from each other while overlapping one sensing control line SCL and extend in the same direction as the sensing control line SCL. Each of the plurality of second active lines AL2 is connected to the sensing control line SCL through a contact hole.

A high power line VDDL, data lines DL1, DL2, DL3, and DL4 and a reference line RL are arranged in a second direction crossing the first direction, for example, in a longitudinal direction.

In the second direction, the high power line VDDL, the first data line DL1, the second data line DL2, the reference line RL, the third data line DL3, and the fourth data line DL4 are arranged in order, and the arrangement may be repeated, but is not limited thereto.

The high power line VDDL, the data lines DL1, DL2, DL3, and DL4, and the reference line RL may be formed of the same material on the same layer. The high power line VDDL, the data lines DL1, DL2, DL3, and DL4 and the reference line RL may be positioned below the gate line GL and the sensing control line SCL with an insulating layer therebetween.

The high power line VDDL, the data lines DL1, DL2, DL3, and DL4 and the reference line RL overlap and cross the first active line AL1 and the second active line AL2. A plurality of contact holes for connecting the plurality of first active lines AL1 and the one gate line GL and a plurality of contact holes for connecting the plurality of second active lines AL2 and the one sensing control line SCL may be disposed so as not to overlap the high power line VDDL, the data lines DL1, DL2, DL3, and DL4 and the reference line RL.

A first sub-pixel SP1 may be disposed between the high power line VDDL and the first data line DL1, a second sub-pixel SP2 may be disposed between the second data line DL2 and the reference line RL, a third sub-pixel SP3 may be disposed between the reference line RL and the third data line DL3, and a fourth sub-pixel SP4 may be disposed between the fourth data line DL4 and the high power line VDDL.

The first data line DL1 supplies a data signal to the first sub-pixel SP1, the second data line DL2 supplies a data signal to the second sub-pixel SP2, the third data line DL3 supplies a data signal to the third sub-pixel SP3, and the fourth data line DL4 supplies a data signal to the fourth sub-pixel SP4.

Each of the sub-pixels SP1, SP2, SP3, and SP4 may include a light emitting area, a line area, and a circuit area. In this case, the light emitting area may not overlap the line area and the circuit area, and in this case, the electroluminescence display device may be configured in a bottom emission tyle.

Throughout the present disclosure, the light emitting area is an area in which light emission occurs, the line area is an area in which lines including the high power line VDDL, the data lines DL1, DL2, DL3, and DL4, the reference line RL, the gate line GL, and the scan control line SCL are disposed, and the circuit area is an area in which thin film transistors T1, T2, and T3 and a capacitor are disposed.

The first data line DL1 and the second data line DL2 may be disposed adjacent to each other without other wirings being disposed therebetween. The third data line DL3 and the fourth data line DL4 may also be disposed adjacent to each other without other wirings being disposed therebetween.

A switching thin film transistor T1, a driving thin film transistor T2, and a sensing thin film transistor T3 are disposed in the circuit area of each of the first to fourth sub-pixels.

The switching thin film transistor T1 includes a first gate electrode G1, a first source electrode S1, a first drain electrode D1, and a first active layer A1.

The first gate electrode G1 may be formed of a part of the gate line GL, but is not limited thereto and may be formed in a structure branched from the gate line GL.

The first source electrode S1 may be connected to a portion branched from the data lines DL1, DL2, DL3, and DL4 through a contact hole, and may be connected to one end of the first active layer A1 through a contact hole.

The first drain electrode D1 may be disposed on the same layer as the first source electrode S1, and may be connected to the other end of the first active layer A1 through a contact hole.

The first source electrode S1 and the first drain electrode D1 may be formed of the same material as the first gate electrode G1, but are not limited thereto.

The first active layer A1 may be connected to the first source electrode S1 and the first drain electrode D1 through a contact hole, respectively, to function as an electron moving channel.

The driving thin film transistor T2 includes a second gate electrode G2, a second source electrode S2, a second drain electrode D2, and a second active layer A2.

The second gate electrode G2 may be connected to the first drain electrode D1 of the switching thin film transistor T1. The second gate electrode G2 may be integrally formed with the first drain electrode D1, but is not limited thereto.

The second source electrode S2 may be connected to one end of the second active layer A2 through a contact hole while facing the second drain electrode D2. The second source electrode S2 may be connected to a light blocking layer LS thereunder through a contact hole.

The light blocking layer LS may be formed of the same material in the same layer as the high power line VDDL, the data lines DL1, DL2, DL3, and DL4, and the reference line RL. The light blocking layer LS may overlap the second active layer A2 to block external light from being incident on the second active layer A2. In addition, the light blocking layer LS may function as a capacitor electrode. Specifically, the light blocking layer LS and the second gate electrode G2 may overlap each other with an insulating layer therebetween, so that a capacitor may be formed by the light blocking layer LS and the second gate electrode G2.

The second source electrode S2 may be connected to the first electrode 200 through a contact hole.

The second drain electrode D2 may face the second source electrode S2 and may be connected to the other end of the second active layer A2 through a contact hole.

The second drain electrode D2 is connected to the high power line VDDL through a high power line connection part VDDL_CP. The high power line connection part VDDL_CP is connected to the high power line VDDL through a contact hole. The high power line connection part VDDL_CP may extend in the first direction and may be connected to the second drain electrode D2 of the first to fourth subpixels. The high power line connection part VDDL_CP and the second drain electrode D2 may be integrally formed.

The second source electrode S2 and the second drain electrode D2 may be formed of the same material as the second gate electrode G2, but are not limited thereto.

In some cases, a configuration connected to the high power line VDDL through the high power line connection part VDDL_CP may function as a source electrode, and a configuration connected to the first electrode 200 may function as a drain electrode.

The second active layer A2 may be connected to the second source electrode S2 and the second drain electrode D2 through a contact hole, respectively, to function as an electron moving channel. The second active layer A2 may be formed of the same material on the same layer as the first active layer A1.

The sensing thin film transistor T3 includes a third gate electrode G3, a third source electrode S3, a third drain electrode D3, and a third active layer A3.

The third gate electrode G3 may be formed as a part of the sensing control line SCL, but is not limited thereto and may be formed in a structure branched from the sensing control line SCL.

The third source electrode S3 may be connected to the light blocking layer LS through a contact hole, and thus may be electrically connected to the second source electrode S2 of the driving thin film transistor T2 through the light blocking layer LS. The third source electrode S3 may be connected to one end of the third active layer A3 through a contact hole while facing the third drain electrode D3.

The third drain electrode D3 may be connected to the other end of the third active layer A3 through a contact hole while facing the third source electrode S3 on the same layer as the third source electrode S3.

The third drain electrode D3 is connected to the reference line RL through a reference line connection part RL_CP.

The reference line connection part RL_CP is connected to the reference line RL through a contact hole. The reference line connection part RL_CP may extend in the first direction and may be connected to the third drain electrode D3 of the first to fourth subpixels. The reference line connection part RL_CP and the third drain electrode D3 may be integrally formed.

The third active layer A3 may be connected to the third source electrode S3 and the third drain electrode D3 through a contact hole, respectively, to function as an electron moving channel. The third active layer A3 may be formed of the same material on the same layer as the first active layer A1.

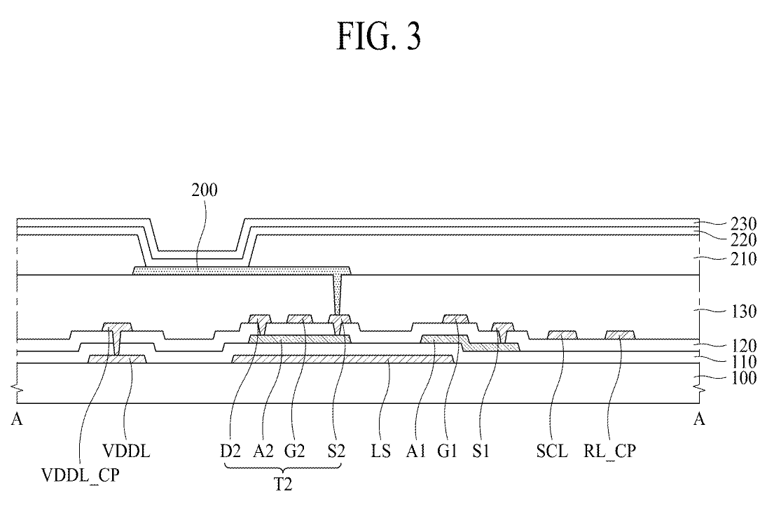

FIG. 3 is a cross-sectional view of an electroluminescent display device according to an embodiment of the present disclosure, which corresponds to a cross-section taken along line A-A of FIG. 2.

As can be seen from FIG. 3, a high power line VDDL and a light blocking layer LS are disposed on the substrate 100 to be spaced apart from each other.

The substrate 100 may be made of glass or plastic, but is not limited thereto. The electroluminescent display device according to an embodiment of the present disclosure may be made of a bottom emission type, and accordingly, a transparent material may be used as a material of the substrate 100.

The high power line VDDL and the light blocking layer LS may be patterned through the same process in the same layer using the same material.

A first insulating layer 110 is disposed on the high power line VDDL and the light blocking layer LS.

The first insulating layer 110 may be disposed on an entire surface of the substrate 100 except for the contact hole area. The first insulating layer 110 may be formed of an inorganic insulating material.

A second active layer A2 and a first active layer A1 are disposed on the first insulating layer 110 to be spaced apart from each other.

At least a portion of the second active layer A2 and the first active layer A1 may overlap the light blocking layer LS, so that light entering under the substrate 100 may be blocked by the light blocking layer LS to prevent the light from entering at least a portion of the second active layer A2 and the first active layer A1.

The second active layer A2 and the first active layer A1 may be formed of the same material through the same process in the same layer.

A second insulating layer 120 is disposed on the second active layer A2 and the first active layer A1.

The second insulating layer 120 may be disposed on the entire surface of the substrate 100 except for a contact hole area. However, the present disclosure is not limited thereto, and the second insulating layer 120 may be formed in the same pattern as a high power line connection part VDDL_CP, a second drain electrode D2, a second gate electrode G2, a first gate electrode G1, a first source electrode S1, a sensing control line SCL, and a reference line connection part RL_CP except for the contact hole area.

The second insulating layer 120 may be made of an inorganic insulating material.

The high power line connection part VDDL_CP, the second drain electrode D2, the second gate electrode G2, the second source electrode S2, the first gate electrode G1, the first source electrode S1, the sensing control line SCL, and the reference line connection part RL_CP are disposed on the second insulating layer 120 to be spaced apart from each other.

The high power line connection part VDDL_CP overlaps the high power line VDDL and is connected to the high power line VDDL through a contact hole disposed in the first insulating layer 110 and the second insulating layer 120.

The second drain electrode D2 overlaps the second active layer A2, and is connected to one end of the second active layer A2 through a contact hole disposed in the second insulating layer 120.

The second gate electrode G2 overlaps the second active layer A2, and is disposed in an area between the second drain electrode D2 and the second source electrode S2.

The second source electrode S2 overlaps the second active layer A2, and is connected to the other end of the second active layer A2 through a contact hole disposed in the second insulating layer 120.

The first gate electrode G1 overlaps the first active layer A1.

The first source electrode S1 overlaps the first active layer A1, and is connected to the first active layer A1 through a contact hole disposed in the second insulating layer 120.

The sensing control line SCL may be disposed between the first source electrode S1 and the reference line connection part RL_CP.

The high power line connection part VDDL_CP, the second drain electrode D2, the second gate electrode G2, the second source electrode S2, the first gate electrode G1, the first source electrode S1, the sensing control line SCL, and the reference line connection part RL_CP may be patterned through the same process in the same layer using the same material.

A third insulating layer 130 may be disposed on the high power source line connection part VDDL_CP, the second drain electrode D2, the second gate electrode G2, the first gate electrode G1, the first source electrode S1, the sensing control line SCL, and the reference line connection part RL_CP.

The third insulating layer 130 may include a planarization layer made of an organic insulating material. The third insulating layer 130 may be formed of a plurality of insulating layers, and for example, may have a two-layer structure including a passivation layer made of an inorganic material and a planarization layer made of an organic material.

A first electrode 200 and a bank 210 are disposed on the third insulation layer 130.

The first electrode 200 may function as an anode. The first electrode 200 is connected to the second source electrode S2 through a contact hole disposed on the third insulating layer 130. In some cases, the first electrode 200 may be connected to the second drain electrode D2 through a contact hole disposed on the third insulating layer 130.

The first electrode 200 may include a transparent electrode or a translucent electrode. Accordingly, light emitted from a light emitting layer 220 may pass through the first electrode 200 and may proceed in a downward direction.

The bank 210 is disposed on the third insulation layer 130 while covering both ends of the first electrode 200. A portion of the first electrode 200 exposed without being covered by the bank 210 may be a light emitting area.

A light emitting layer 220 is disposed on the first electrode 200 and the bank 210.

The light emitting layer 220 may be continuous without being disconnected between the plurality of sub-pixels, and in this case, the light emitting layer 200 may emit white light. The light emitting layer 220 emitting white light may include a stack including a blue light emitting layer and a stack including a yellow green light emitting layer. The light emitting layer 200 emitting white light may include a stack including a blue light emitting layer, a stack including a green light emitting layer, and a stack including a red light emitting layer.

The light emitting layer 220 may include a blue light emitting layer, a green light emitting layer, and a red light emitting layer patterned for each of the plurality of sub-pixels.

A second electrode 230 is disposed on the light emitting layer 220.

The second electrode 230 may function as a cathode. The second electrode 230 may include a reflective electrode. Accordingly, the light emitted from the light emitting layer 220 may be reflected from the second electrode 230 and may proceed in the downward direction. The second electrode 230 may be entirely disposed on the plurality of sub-pixels and a boundary therebetween.

Although not shown, an encapsulation layer, a color filter, a touch sensor, and the like may be additionally disposed on the second electrode 230.

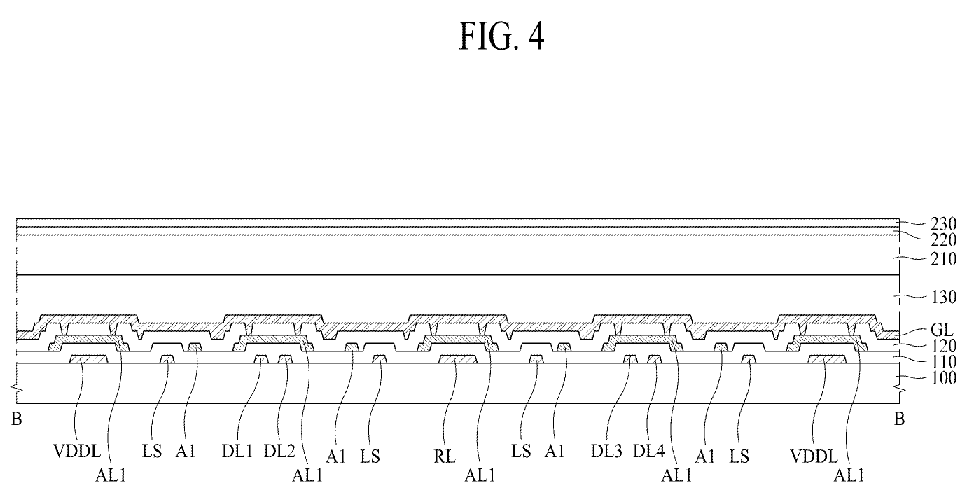

FIG. 4 is a cross-sectional view of an electroluminescent display device according to an embodiment of the present disclosure, which corresponds to a cross-section taken along line B-B of FIG. 2.

As shown in FIG. 4, a high power line VDDL, a light blocking layer LS, a data line DL1, DL2, DL3, DL4, and a reference line RL are disposed on the substrate 100.

The light blocking layer LS is disposed between one high power line VDDL and the first data line DL1, between the second data line DL2 and the reference line RL, between the reference line RL and the third data line DL3, and between the fourth data line DL4 and the other high power line VDDL.

A first insulating layer 110 is disposed on the high power source line VDDL, the light blocking layer LS, the data lines DL1, DL2, DL3, and DL4, and the reference line RL, and a plurality of first active lines AL1 and a plurality of first active layers A1 are disposed on the first insulating layer 110.

The plurality of first active lines AL1 and the plurality of first active layers A1 may be patterned using the same semiconductor material through the same process in the same layer. The plurality of first active lines AL1 and the plurality of first active layers A1 are spaced apart from each other. For example, one first active layer A1 may be disposed between two first active lines AL1.

One first active line AL1 may have a width wider than the high power line VDDL while overlapping an entire high power line VDDL. For example, a left end of one first active line AL1 is located on a left side of a left end of the high power line VDDL, and a right end of one first active line AL1 is located on a right side of a right end of the high power line VDDL.

The other first active line AL1 may have a width wider than an entire width of the first data line DL1 and the second data line DL2 while overlapping an entire first data line DL1 and the second data line DL2. For example, a left end of the other first active line AL1 is located on a left side of a left end of the first data line DL1, and a right end of the other first active line AL1 is located on a right side of a right end of the second data line DL2.

Another first active line AL1 may have a width wider than the reference line RL while overlapping an entire reference line RL. For example, a left end of another first active line AL1 is located on a left side of a left end of the reference line RL, and a right end of another first active line AL1 is located on a right side of a right end of the reference line RL.

Another first active line AL1 may have a width wider than an entire width of the third data line DL3 and the fourth data line DL4 while overlapping an entire third data line DL3 and the fourth data line DL4. For example, a left end of another first active line AL1 is located on a left side of a left end of the third data line DL3, and a right end of another first active line AL1 is located on a right side of a right end of the fourth data line DL4.

A second insulating layer 120 is disposed on the plurality of first active lines AL1 and the plurality of first active layers A1, and a gate line GL is disposed on the second insulating layer 120.

The gate line GL is connected to the plurality of first active lines AL1 through contact holes disposed in the second insulating layer 120. Specifically, the gate line GL is connected to one side and the other side of each of the plurality of first active lines AL1 through contact holes disposed in the second insulating layer 120.

A third insulating layer 130 is disposed on the gate line GL, a bank 210 is disposed on the third insulating layer 130, a light emitting layer 220 is disposed on the bank 210, and a second electrode 230 is disposed on the light emitting layer 220.

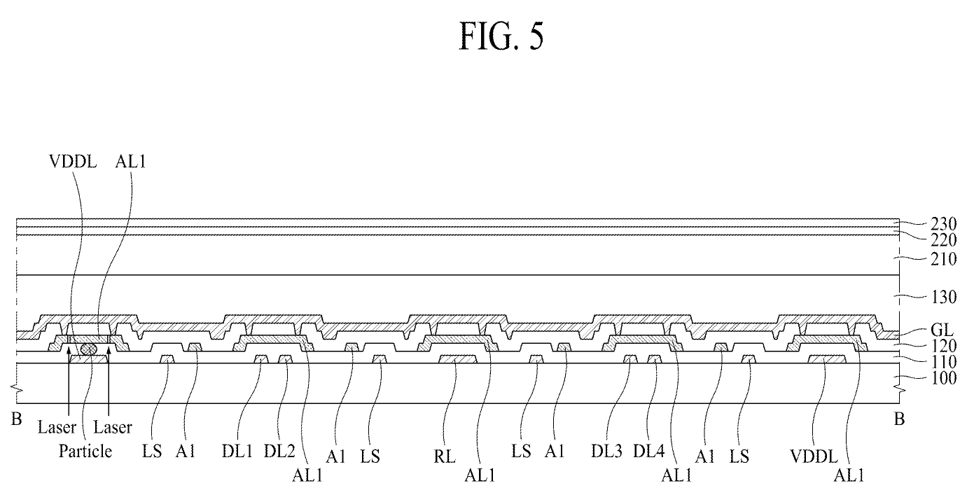

FIG. 5 is a cross-sectional view of an electroluminescent display device according to an embodiment of the present disclosure, which is a view showing a method of repairing a short defect caused by particles in FIG. 4.

As shown in FIG. 5, for example, as particles are formed between the high power line VDDL and the first active line AL1 disposed on the high power line VDDL, the high power line VDDL and the first active line AL1 may be electrically connected, resulting in a short defect between the high power line VDDL and the gate line GL.

In this case, an electrical connection between the first active line AL1 and the gate line GL may be cut off by irradiating a laser from a lower side of the substrate 100 to cut one side and the other side of the first active line AL1, and accordingly, a short defect may be repaired between the high power line VDDL and the gate line GL.

Specifically, the laser may be irradiated to a specific area of the first active line AL1 in an area where the short defect occurs. The specific area of the first active line AL1 may be an area inside two contact hole areas which is disposed on one side and the other side of the first active line AL1 and connects the first active line AL1 and the gate line GL. Accordingly, a part of the first active line AL1 in contact with the particle may be cut off to disconnect an electrical connection with the gate line GL.

One side area of the first active line AL1 cut off by the laser irradiation corresponds to an area between a contact hole of one side connecting the first active line AL1 and the gate line GL and a left end of the high power line VDDL. And, the other side area of the first active line AL1 cut off by the laser irradiation corresponds to an area between a contact hole of the other side connecting the first active line AL1 and the gate line GL and a right end of the high power line VDDL.

Although not shown, even when a short defect occurs between the data lines DL1, DL2, DL3, and DL4 and the gate line GL by forming particles between the data lines DL1, DL2, DL3, and DL4 and the first active line AL1, the short defect may be repaired by cutting one side and the other side of the first active line AL1 in the short defect area.

Similarly, when a short defect occurs between the reference line RL and the gate line GL by forming particles between the reference line RL and the first active line AL1, the short defect may be repaired by cutting one side and the other side of the first active line AL1 in the short defect area.

As described above, according to an embodiment of the present disclosure, the first active line AL1 connected to the gate line GL is disclosed below the gate line GL. In this case, when a short defect occurs due to a particle, a short defect between the high power line VDDL and the gate line GL, a short defect between the data lines DL1, DL2, DL3, and DL4 and the gate line GL and a short defect between the reference line RL and the gate line GL may be repaired by a simple method of disconnecting the first active line AL1 by irradiating the laser from the lower side of the substrate 100.

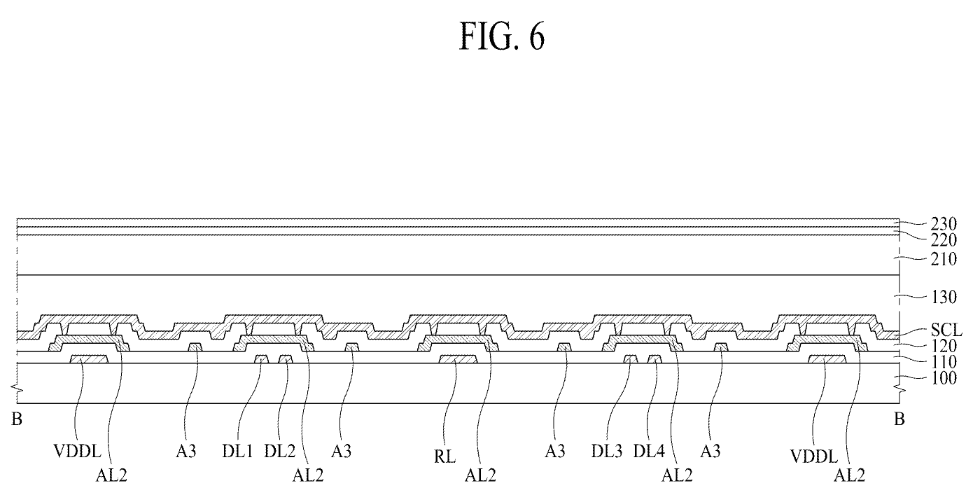

FIG. 6 is a cross-sectional view of an electroluminescent display device according to an embodiment of the present disclosure, which corresponds to a cross section taken along line C-C of FIG. 2.

As shown in FIG. 6, the high power line VDDL, the data lines DL1, DL2, DL3, and DL4 and the reference line RL are disposed on the substrate 100.

A first insulating layer 110 is disposed on the high power line VDDL, the data lines DL1, DL2, DL3, and DL4, and the reference line RL, and a plurality of second active lines AL2 and a plurality of third active layers A3 are formed on the first insulating layer 110.

The plurality of second active lines AL2 and the plurality of third active layers A3 may be patterned using the same material through the same process in the same layer. The plurality of second active lines AL2 and the plurality of third active layers A3 are spaced apart from each other. One third active layer A3 may be disposed between two second active lines AL2.

One second active line AL2 may have a width wider than the high power line VDDL while overlapping an entire high power line VDDL. For example, a left end of one second active line AL2 is located on a left side of a left end of the high power line VDDL, and a right end of one second active line AL2 is located on a right side of a right end of the high power line VDDL.

The other second active line AL2 may have a width wider than an entire width of the first data line DL1 and the second data line DL2 while overlapping an entire first data line DL1 and the second data line DL2. For example, a left end of the other second active line AL2 is located on a left side of a left end of the first data line DL1, and a right end of the other second active line AL2 is located on a right side of a right end of the second data line DL2.

Another second active line AL2 may have a width wider than the reference line RL while overlapping an entire reference line RL. For example, a left end of another second active line AL2 is located on a left side of a left end of the reference line RL, and a right end of another second active line AL2 is located on a right side of a right end of the reference line RL.

Another second active line AL2 may have a width wider than an entire width of the third data line DL3 and the fourth data line DL4 while overlapping an entire third data line DL3 and the fourth data line DL4. For example, a left end of another second active line AL2 is located on a left side of a left end of the third data line DL3, and a right end of another second active line AL2 is located on a right side of a right end of the fourth data line DL4.

A second insulating layer 120 is disposed on the plurality of first active lines AL1 and the plurality of first active layers A1, and a gate line GL is formed on the second insulating layer 120.

A second insulating layer 120 is disposed on the plurality of second active lines AL2 and the plurality of third active layers A3, and a sensing control line SCL is disposed on the second insulating layer 120.

The sensing control line SCL is connected to the plurality of second active lines AL2 through a contact hole disposed in the second insulating layer 120. Specifically, the sensing control line SCL is connected to one side and the other side of each of the plurality of second active lines AL2 through a contact hole disposed in the second insulating layer 120.

A third insulating layer 130 is disposed on the sensing control line SCL, a bank 210 is disposed on the third insulating layer 130, a light emitting layer 220 is disposed on the bank 210, and a second electrode 230 is disposed on the light emitting layer 220.

Similar to FIG. 5 described above, when a short defect occurs between the high power line VDDL and the sensing control line SCL by forming particles between the high power line VDDL and the second active line AL2 disposed on the high power line VDDL, the short defect may be repaired by cutting one side and the other side of the second active line AL2 in the short defect area.

In addition, when a short defect occurs between the data lines DL1, DL2, DL3, and DL4 and the sensing control line SCL by forming particles between the data lines DL1, DL2, DL3, and DL4 and the second active line AL2, the short defect may be repaired by cutting one side and the other side of the second active line AL2 in the short defect area.

In addition, when a short defect occurs between the reference line RL and the sensing control line SCL by forming particles between the reference line RL and the second active line AL2, the short defect may be repaired by cutting one side and the other side of the second active line AL2 in the short defect area.

As described above, according to an embodiment of the present disclosure, the second active line AL2 connected to the sensing control line SCL is disclosed below the sensing control line SCL. In this case, when a short defect occurs due to a particle, a short defect between the high power line VDDL and the sensing control line SCL, a short defect between the data lines DL1, DL2, DL3, and DL4 and the sensing control line SCL and a short defect between the reference line RL and the sensing control line SCL may be repaired by a simple method of disconnecting the second active line AL2 by irradiating the laser from the lower side of the substrate 100.

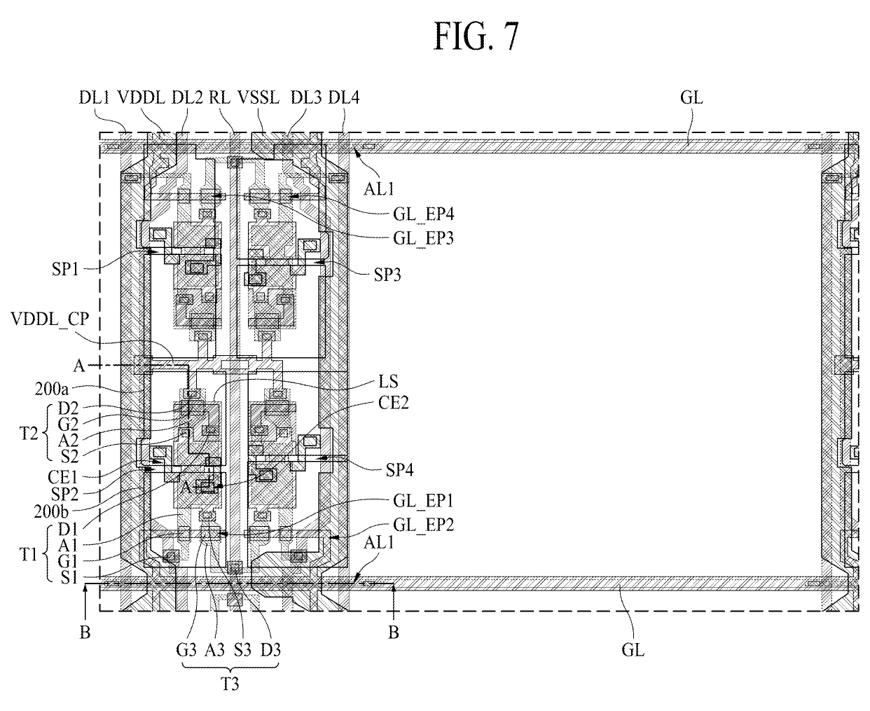

FIG. 7 is a plan view of an electroluminescent display device according to another embodiment of the present disclosure.

As shown in FIG. 7, a plurality of gate lines GLs are arranged in the first direction, for example, in the horizontal direction.

A plurality of gate line extension parts GL_EP1, GL_EP2, GL_EP3, and GL_EP4 are connected to each of the plurality of gate lines GLs. At least a part of the gate line extension part GL_EP1, GL_EP2, GL_EP3, and GL_EP4 extend in a direction different from that of the gate line GL. The gate line extension parts GL_EP1, GL_EP2, GL_EP3, and GL_EP4 may be integrally formed with the gate line GL.

A first gate line extension part GL_EP1 and a second gate line extension part GL_EP2 may extend upward from one gate line GL, and a third gate line extension part GL_EP3 and a fourth gate line extension part GL_EP4 may extend downward from one gate line GL.

For convenience, in FIG. 7, only the third and fourth gate line extension parts GL_EP3 and GL_EP4 are extended to an upper gate line GL, and only the first and second gate line extensions GL_EP1 and GL_EP2 are extended to a lower gate line GL.

The first gate line extension part GL_EP1 may extend upward in the second direction crossing the first direction at one side of the gate line GL, for example, in the vertical direction, and then may extend again to a right along the first direction.

The second gate line extension part GL_EP2 may extend upward in the second direction from the other side of the gate line GL, and then may extend to a left along the first direction.

One end of the first gate line extension part GL_EP1 and one end of the second gate line extension part GL_EP2 may be spaced apart from each other while facing each other with the reference line RL interposed therebetween, and thus, aperture ratio, sharpness, and transparency may be improved compared to a case where they are connected to each other.

The third gate line extension part GL_EP3 may extend downward in the second direction crossing the first direction at one side of the gate line GL, for example, in the vertical direction, and then may extend again to the right along the first direction.

The fourth gate line extension part GL_EP4 may extend downward in the second direction from the other side of the gate line GL and then may extend to the left again along the first direction.

One end of the third gate line extension part GL_EP3 and one end of the fourth gate line extension part GL_EP4 may be spaced apart from each other while facing each other with the reference line RL interposed therebetween, and thus, aperture ratio, sharpness, and transparency may be improved compared to a case where they are connected to each other.

The gate line extension parts GL_EP1, GL_EP2, GL_EP3, and GL_EP4 may be disposed in separate sub-pixels.

The first gate line extension part GL_EP1 may supply a gate signal to the second sub-pixel SP2, the second gate line extension part GL_EP2 may supply a gate signal to the fourth sub-pixel SP4, the third gate line extension part GL_EP3 may supply a gate signal to the first sub-pixel SP1, and the fourth gate line extension part GL_EP4 may supply a gate signal to the third sub-pixel SP3.

A first active line AL1 is disposed to overlap the gate line GL.

The first active line AL1 extends in the same direction as the gate line GL. The first active line AL1 is connected to the gate line GL through a contact hole. The first active line AL1 may not overlap the gate line extension parts GL_EP1, GL_EP2, GL_EP3, and GL_EP4.

A high power line VDDL, a low power line VSSL, a data lines DL1, DL2, DL3, and DL4 and a reference line RL are arranged in the second direction crossing the first direction, for example, in the vertical direction.

In the second direction, a first data line DL1, a second data line DL2, the reference line RL, a third data line DL3, and a fourth data line DL4 are arranged in order, and the arrangement may be repeated, but is not limited thereto.

The high power line VDDL may overlap the first data line DL1 and the second data line DL2, and the low power line VSSL may overlap the third data line DL3 and the fourth data line DL4.

The high power line VDDL may be connected to a high power line connection part VDDL_CP. The high power line connection part VDDL_CP is connected to the high power line VDDL through a contact hole and extends from the high power line VDDL in the first direction. The high power source VDD may be supplied to the plurality of sub-pixels SP1, SP2, SP3, and SP4 through the high power line connection part VDDL_CP.

The data lines DL1, DL2, DL3, and DL4 and the reference line RL may be formed of the same material on the same layer. The data lines DL1, DL2, DL3, and DL4 and the reference line RL may be positioned below the gate line GL with an insulating layer therebetween.

The high power line VDDL and the low power line VSSL may be made of the same material on the same layer. The high power line VDDL and the low power line VSSL may be positioned above the gate line GL with an insulating layer therebetween.

The high power line connection part VDDL_CP may be made of the same material on the same layer as the gate line GL.

The high power line VDDL, the low power line VSSL, the data lines DL1, DL2, DL3, and DL4, and the reference line RL intersect the first active line AL1 while overlapping the first active line AL1.

A plurality of contact holes for connecting the first active line AL1 to the gate line GL may be disposed not to overlap the data lines DL1, DL2, DL3, and DL4 and the reference line RL. In addition, the plurality of contact holes for connecting the first active line AL1 to the gate line GL may be disposed not to overlap the high power line VDDL and the low power line VSSL.

Two sub-pixels SP1 and SP2 are disposed in the vertical direction between the high power line VDDL and the reference line RL or between the second data line DL2 and the reference line RL. In this case, the two sub-pixels SP1 and SP2 may include a first sub-pixel SP1 and a second sub-pixel SP2 separated from each other with the high power line connection part VDDL_CP interposed therebetween. For example, the two sub-pixels SP1 and SP2 may include a first sub-pixel SP1 disposed above the high power line connection part VDDL_CP and a second sub-pixel SP2 disposed below the high power line connection part VDDL_CP.

In addition, two sub-pixels SP3 and SP4 different in the vertical direction are disposed between the reference line RL and the low power line VSSL or between the low power line VSSL and the third data line DL3. In this case, the other two sub-pixels may include a third sub-pixel SP3 disposed above the high power line connection part VDDL_CP and a fourth sub-pixel SP4 disposed below the high power line connection part VDDL_CP.

In this case, the first sub-pixel SP1 faces the third sub-pixel SP3 with the reference line RL interposed therebetween, and the second sub-pixel SP2 faces the fourth sub-pixel SP4 with the reference line RL interposed therebetween.

Accordingly, four sub-pixels SP1, SP2, SP3, and SP4 may be formed by the high power line VDDL, the reference line RL, and the low power line VSSL arranged in the second direction and the high power line connection unit VDDL_CP arranged in the first direction.

Each of the sub-pixels SP1, SP2, SP3, and SP4 may include a light emitting area, a line area, and a circuit area. In this case, the light emitting area may overlap at least a portion of the line area and the circuit area, and in this case, the electroluminescent display device may be configured in a top emission type.

The first data line DL1 and the second data line DL2 may be disposed adjacent to each other without other wirings being disposed therebetween. The third data line DL3 and the fourth data line DL4 may also be disposed adjacent to each other without other wirings being disposed therebetween.

The data lines DL1, DL2, DL3, and DL4 supply a data signal to each of the sub-pixels SP1, SP2, SP3, and SP4.

A switching thin film transistor T1, a driving thin film transistor T2, and a sensing thin film transistor T3 are disposed in the circuit area of each of the four sub-pixels SP1, SP2, SP3, and SP4.

The switching thin film transistor T1 includes a first gate electrode G1, a first source electrode S1, a first drain electrode D1, and a first active layer A1.

The first gate electrode G1 may be formed of a part of the gate line extension parts GL_EP1, GL_EP2, GL_EP3, and GL_EP4.

The first source electrode S1 may be connected to a portion branched from the data lines DL1, DL2, DL3, and DL4 through a contact hole, and may be connected to one end of the first active layer A1 through a contact hole.

The first drain electrode D1 may be disposed on the same layer as the first source electrode S1, and may be connected to the other end of the first active layer A1 through a contact hole.

The first source electrode S1 and the first drain electrode D1 may be formed of the same material as the first gate electrode G1, but are not limited thereto.

The first active layer A1 may be connected to the first source electrode S1 and the first drain electrode D1 through a contact hole, respectively, to function as an electron moving channel.

The driving thin film transistor T2 includes a second gate electrode G2, a second source electrode S2, a second drain electrode D2, and a second active layer A2.

The second gate electrode G2 may be connected to the first drain electrode D1 of the switching thin film transistor T1. The second gate electrode G2 may be integrally formed with the first drain electrode D1, but is not limited thereto.

The second source electrode S2 may be connected to one end of the second active layer A2 through a contact hole while facing the second drain electrode D2. The second source electrode S2 may be connected to a light blocking layer LS thereunder through a contact hole.

The light blocking layer LS may be formed of the same material in the same layer as the data lines DL1, DL2, DL3, and DL4, and the reference line RL. The light blocking layer LS may overlap the second active layer A2 to block external light from being incident on the second active layer A2. In addition, the light blocking layer LS may function as a capacitor electrode. Specifically, the light blocking layer LS and the second gate electrode G2 may overlap each other with an insulating layer therebetween, so that a capacitor may be formed by the light blocking layer LS and the second gate electrode G2.

The second source electrode S2 may be connected to two connection electrodes CE1 and CE2 through contact holes. The two connection electrodes CE1 and CE2 may be formed of the same material on the same layer as the high power line VDDL and the low power line VSSL. A first connection electrode CE1 may be connected to a first sub-electrode 200a that functions as one anode through a contact hole, and a second connection electrode CE2 may be connected to a second sub-electrode 200b that functions as the other anode through a contact hole. Accordingly, the first electrodes 200a and 200b of one sub-pixel may be formed of two sub-electrodes 200a and 200b that are spaced apart from each other. The two sub-electrodes 200a and 200b may be driven at the same time, or only one sub-electrode 200a and 200b may be driven by a repair process for solving defects.

The second drain electrode D2 may face the second source electrode S2 and may be connected to the other end of the second active layer A2 through a contact hole.

The second drain electrode D2 is connected to the high power line VDDL through a high power line connection part VDDL_CP. The high power line connection part VDDL_CP is connected to the high power line VDDL through a contact hole. The high power line connection part VDDL_CP may extend in the first direction and may be connected to the second drain electrode D2 of the first to fourth subpixels. The high power line connection part VDDL_CP and the second drain electrode D2 may be integrally formed.

The second source electrode S2 and the second drain electrode D2 may be formed of the same material as the second gate electrode G2, but are not limited thereto.

In some cases, a configuration connected to the high power line VDDL through the high power line connection part VDDL_CP may function as a source electrode, and a configuration connected to the first electrodes 200a and 200b through the connection electrodes CE1 and CE2 may function as a drain electrode.

The second active layer A2 may be connected to the second source electrode S2 and the second drain electrode D2 through a contact hole, respectively, to function as an electron moving channel. The second active layer A2 may be formed of the same material on the same layer as the first active layer A1.

The sensing thin film transistor T3 includes a third gate electrode G3, a third source electrode S3, a third drain electrode D3, and a third active layer A3.

The third gate electrode G3 may be formed of a part of the gate line extension parts GL_EP1, GL_EP2, GL_EP3, and GL_EP4.

The third source electrode S3 may be integrally formed with the second source electrode S2 of the driving thin film transistor T2. Alternatively, the third source electrode S3 may be connected to the light blocking layer LS through a contact hole, and thus may be electrically connected to the second source electrode S2 of the driving thin film transistor T2 through the light blocking layer LS. The third source electrode S3 may be connected to one end of the third active layer A3 through a contact hole.

The third drain electrode D3 may be formed of the same material on the same layer as the third source electrode S3, and may be connected to the other end of the third active layer A3 through a contact hole. In addition, the third drain electrode D3 may be connected to the reference line RL through a contact hole.

The third active layer A3 may be connected to the third source electrode S3 and the third drain electrode D3 through a contact hole, respectively, to function as an electron moving channel. The third active layer A3 may be formed of the same material on the same layer as the first active layer A1.

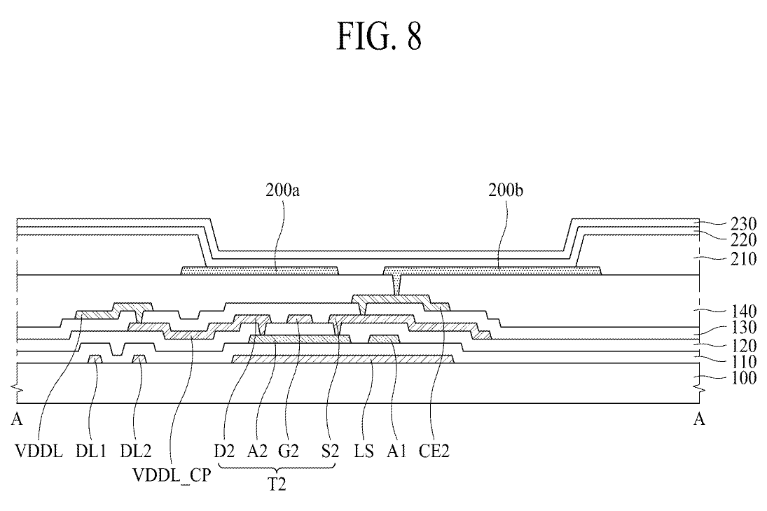

FIG. 8 is a cross-sectional view of an electroluminescent display device according to another embodiment of the present disclosure, which corresponds to a cross-section taken along line A-A of FIG. 7.

As shown in FIG. 8, the data lines DL1 and DL2 and the light blocking layer LS are disposed on the substrate 100 to be spaced apart from each other.

The substrate 100 may be made of glass or plastic, but is not limited thereto. The electroluminescent display device according to an embodiment of the present disclosure may be made of a bottom emission type, and accordingly, a transparent material may be used as a material of the substrate 100.

The data lines DL1 and DL2 and the light blocking layer LS may be patterned through the same process in the same layer using the same material.

A first insulating layer 110 is disposed on the data lines DL1 and DL2 and the light blocking layer LS.

The first insulating layer 110 may be disposed on an entire surface of the substrate 100 except for the contact hole area. The first insulating layer 110 may be formed of an inorganic insulating material.

A second active layer A2 and a first active layer A1 are disposed on the first insulating layer 110.

At least a portion of the second active layer A2 and the first active layer A1 may overlap the light blocking layer LS, so that light entering under the substrate 100 may be blocked by the light blocking layer LS to prevent the light from entering at least a portion of the second active layer A2 and the first active layer A1.

A second insulating layer 120 is disposed on the second active layer A2 and the first active layer A1.

The second insulating layer 120 may be disposed on the entire surface of the substrate 100 except for a contact hole area. However, the present disclosure is not limited thereto, and the second insulating layer 120 may be formed in the same pattern as a high power line connection part VDDL_CP, a second drain electrode D2, a second gate electrode G2, and a second source electrode S2 except for the contact hole area.

The second insulating layer 120 may be made of an inorganic insulating material.

The high power line connection part VDDL_CP, the second drain electrode D2, the second gate electrode G2, and the second source electrode S2 are disposed on the second insulating layer 120 to be spaced apart from each other.

The high power line connection part VDDL_CP may be integrally formed with the second drain electrode D2.

The second drain electrode D2 overlaps the second active layer A2, and is connected to one end of the second active layer A2 through a contact hole disposed in the second insulating layer 120.

The second gate electrode G2 overlaps the second active layer A2, and is disposed in an area between the second drain electrode D2 and the second source electrode S2.

The second source electrode S2 overlaps the second active layer A2, and is connected to the other end of the second active layer A2 through a contact hole disposed in the second insulating layer 120. The second source electrode S2 may overlap the first active layer A1, but is not connected to the first active layer A1.

The high power line connection part VDDL_CP, the second drain electrode D2, the second gate electrode G2, and the second source electrode S2 may be patterned through the same process in the same layer of the same material.

A third insulating layer 130 may be disposed on the high power source line connection part VDDL_CP, the second drain electrode D2, the second gate electrode G2, and the second source electrode S2.

The third insulating layer 130 may be disposed on an entire surface of the substrate 100 except for a contact hole area. The third insulating layer 130 may be made of an inorganic insulating material.

A high power line VDDL and a second connection electrode CE2 are disposed on the third insulation layer 130.

The high power line VDDL and the second connection electrode CE2 may be patterned using the same material through the same process in the same layer.

The high power line VDDL may be connected to the high power line connection part VDDL_CP through a contact hole disposed in the third insulating layer 130, and the second connection electrode CE2 may be connected to the second source electrode S2 through a contact hole disposed in the third insulating layer 130.

Thus, the high power line VDDL overlaps the high power line connection part VDDL_CP, and the second connection electrode CE2 overlaps the second source electrode S2.

A fourth insulating layer 140 is disposed on the high power source line VDDL and the second connection electrode CE2. The fourth insulating layer 140 may include a planarization layer made of an organic insulating material. The fourth insulating layer 140 may be formed of a plurality of insulating layers, and for example, may have a two-layer structure including a passivation layer made of an inorganic material and a planarization layer made of an organic material.

A first electrode 200a and 200b and a bank 210 are disposed on the fourth insulation layer 140.

Each of the first electrodes 200a and 200b may include a first sub-electrode 200a and a second sub-electrode 200b that are spaced apart from each other while functioning as an anode. The second sub-electrode 200b is connected to the second connection electrode CE2 through a contact hole disposed on the fourth insulation layer 140. Therefore, the second sub-electrode 200b is electrically connected to the second source electrode S2 through the second connection electrode CE2. In some cases, the second sub-electrode 200b may be electrically connected to the second drain electrode D2 through the second connection electrode CE2.

The first electrodes 200a and 200b may include reflective electrodes. Accordingly, light emitted from the light emitting layer 220 may be reflected from the first electrodes 200a and 200b and may proceed in an upward direction.

The bank 210 is disposed on the fourth insulation layer 140 while covering both ends of the first electrode 200a and 200b. A portion of the first electrode 200a and 200b exposed without being covered by the bank 210 may be a light emitting area.

Although not illustrated, the bank 210 may be formed to additionally cover a spaced area between the first sub-electrode 200a and the second sub-electrode 200b.

A light emitting layer 220 is disposed on the first electrodes 200a and 200b and the bank 210, and a second electrode 230 is disposed on the light emitting layer 220.

The light emitting layer 220 is the same as the above-described embodiment.

The second electrode 230 may function as a cathode. The second electrode 230 may include a transparent electrode or a translucent electrode. Accordingly, the light emitted from the light emitting layer 220 may pass through the second electrode 230 and proceed in an upward direction. The second electrode 230 may be entirely formed on the plurality of sub-pixels and a boundary therebetween.

In addition, as in the above-described embodiment, an encapsulation layer, a color filter, and a touch sensor may be additionally configured on the second electrode 230.

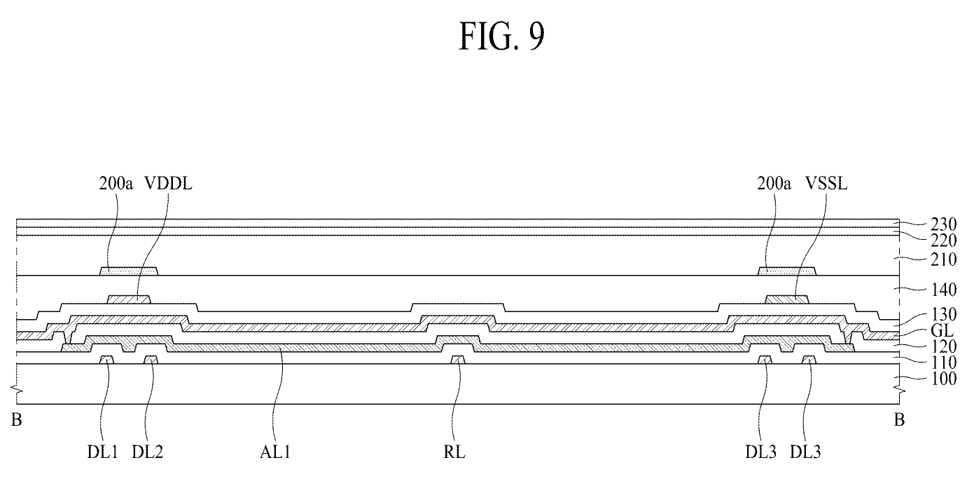

FIG. 9 is a cross-sectional view of an electroluminescent display device according to another embodiment of the present disclosure, which corresponds to a cross-section taken along line B-B of FIG. 7.

As shown in FIG. 9, a data line DL1, DL2, DL3, DL4, and a reference line RL are disposed on the substrate 100.

A first insulating layer 110 is disposed on the data lines DL1, DL2, DL3, and DL4, and the reference line RL, and a first active lines AL1 are disposed on the first insulating layer 110.

The first active line AL1 may overlap an entire area of data lines DL1, DL2, DL3, and DL4 and the reference line RL and have a width wider than the entire width of the data lines DL1, DL2, DL3, and DL4 and the reference line RL. For example, a left end of the first active line AL1 is located on a left side of a left end of the first data line DL1, and a right end of the first active line AL1 is located on a right side of a right end of the fourth data line DL4.

A second insulating layer 120 is disposed on the first active lines AL1 and a gate line GL is disposed on the second insulating layer 120.

The gate line GL is connected to the first active line AL1 through a contact hole disposed in the second insulating layer 120. Specifically, the gate line GL is connected to one side and the other side of the first active line AL1 through a contact hole disposed in the second insulating layer 120. In this case, a contact hole corresponding to one side of the first active line AL1 is located at the left side of the left end of the first data line DL1, and a contact hole corresponding to the other side of the first active line AL1 may be located at the right side of the right end of the fourth data line DL4.

A third insulating layer 130 is disposed on the gate line GL, and a high power line VDDL and a low power line VSSL are disposed on the third insulating layer 130.

The fourth insulating layer 140 is disposed on the high power line VDDL and the low power line VSSL, first electrodes 200a and 200b are disposed on the fourth insulating layer 140, a bank 210 is disposed on the first electrodes 200a and 200b, a light emitting layer 220 is disposed on the bank 210, and a second electrode 230 is disposed on the light emitting layer 220.

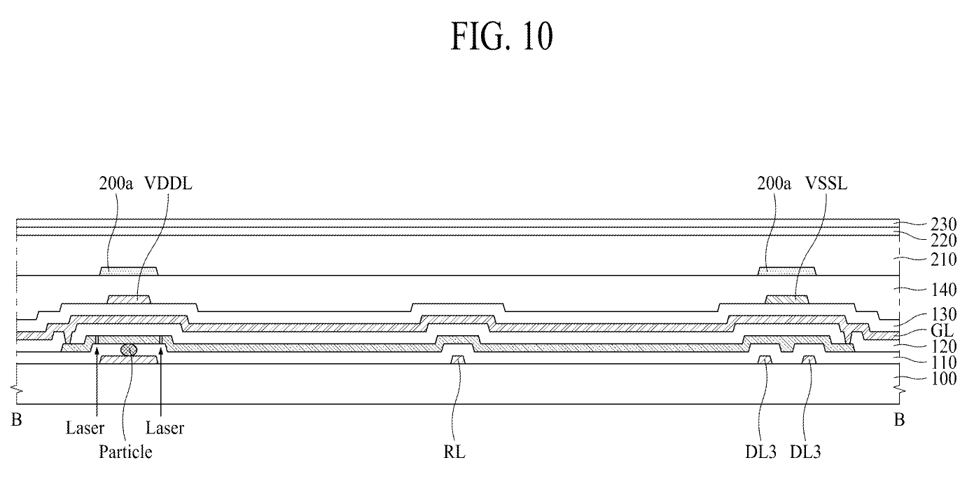

FIG. 10 is a cross-sectional view of an electroluminescent display device according to an embodiment of the present disclosure, which is a view showing a method of repairing a short defect caused by particles in FIG. 9.

As shown in FIG. 10, for example, as particles are formed between the first data line DL1 and the first active line AL1 disposed on the first data line DL1, the first data line DL1 and the first active line AL1 may be electrically connected, resulting in a short defect between the first data line DL1 and the gate line GL.

In this case, an electrical connection between the first active line AL1 and the gate line GL may be cut off by irradiating a laser from a lower side of the substrate 100 to cut one side and the other side of the first active line AL1, and accordingly, a short defect may be repaired between the first data line DL1 and the gate line GL.

Specifically, the laser may be irradiated to one side area and the other side area of the active line AL1 corresponding to an outside of the first data line DL1 in an area where the short defect occurs. By disconnecting a portion of the first active line AL1 in which the short defect occurs in contact with the particle and the remaining portion, an electrical connection between a portion of the first active line AL1 in which the short defect occurs and the gate line GL may be blocked. In this case, the remaining portion of the first active line AL1 except for the one portion is still connected to the gate line GL through a contact hole.

One side area of the first active line AL1 cut off by the laser irradiation corresponds to an area between a contact hole of one side connecting the first active line AL1 and the gate line GL and the left end of the first data line DL1. And, the other side area of first active line AL1 cut off by the laser irradiation corresponds to an area between the right end of the first data line DL1 and the left end of the second data line DL2.

Although not shown, even when a short defect occurs between at least one of the second, third, and fourth data lines DL2, DL3, and DL4 and the reference line RL by forming particles between at least one of the second, third, and fourth data lines DL2, DL3, and DL4 and the reference line RL, the short defect may be repaired by cutting one side and the other side of the first active line AL1 in the short defect area.

As described above, according to an embodiment of the present disclosure, the first active line AL1 connected to the gate line GL is disclosed below the gate line GL. In this case, when a short defect occurs due to a particle, a short defect between the data lines DL1, DL2, DL3, and DL4 and the gate line GL and a short defect between the reference line RL and the gate line GL may be repaired by a simple method of disconnecting the first active line AL1 by irradiating the laser from the lower side of the substrate 100.

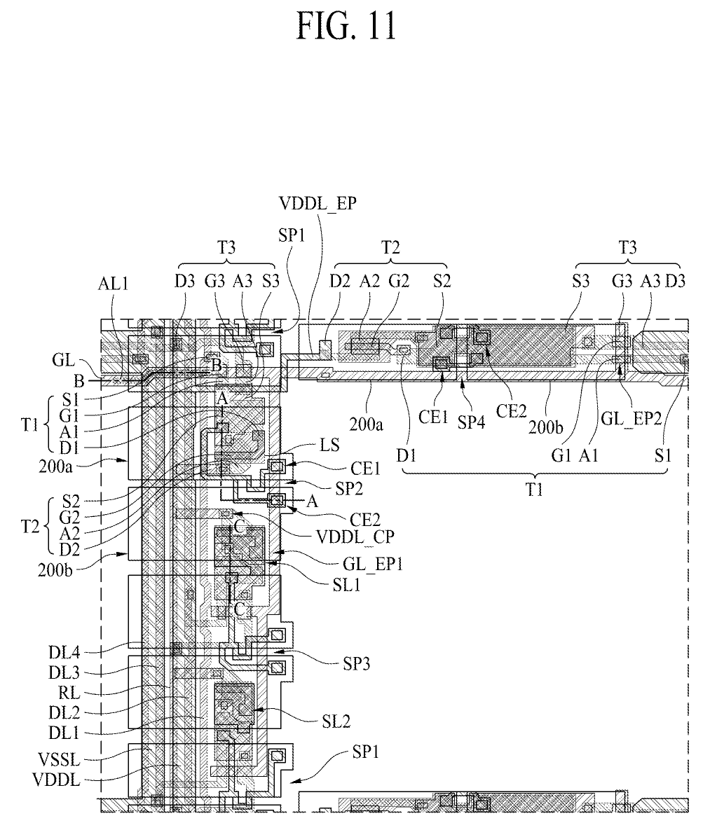

FIG. 11 is a plan view of an electroluminescent display device according to another embodiment of the present disclosure.

As shown in FIG. 11, a plurality of gate lines GLs are arranged in the first direction, for example, in the horizontal direction.

A first gate line extension part GL_EP1 and a second gate line extension part GL_EP2 may extend from the gate line GL. The gate line extension parts GL_EP1 and GL_EP2 may be integrally formed with the gate line GL.

The first gate line extension part GL_EP1 may extend downward from the gate line GL, and the second gate line extension part GL_EP2 may extend upward from the gate line GL.

The first gate line extension part GL_EP1 may include a first portion and a second portion. The first portion is an area extending downward from one side of the gate line GL in the second direction, for example, in the vertical direction, and the second portion is an area extending from the first portion to the left in the first direction, for example, in the horizontal direction. The first gate line extension part GL_EP1 includes a structure in which a combination of the first portion and the second portion is repeated twice, and thus may be extended to a plurality of sub-pixels arranged in the second direction, for example, a third sub-pixel SP3 and a first sub-pixel SP1.

The second gate line extension part GL_EP2 may extend upward in the second direction from the other side of the gate line GL, and thus may extend to another sub-pixel arranged in the first direction, for example, a fourth sub-pixel SP4.

For example, the gate line GL may supply a gate signal to the second sub-pixel SP2, the first gate line extension part GL_EP1 may supply the same gate signal to the third sub-pixel SP3 and the first sub-pixel SP1, and the second gate line extension part GL_EP2 may supply the same gate signal to the fourth sub-pixel SP4. In this case, the first sub-pixel to the third sub-pixel SP1, SP2, and SP3 may be arranged in the second direction, for example, in the vertical direction, and the fourth sub-pixel SP4 may be arranged in the horizontal direction from the right side of the first sub-pixel, for example.

A first active line AL1 is disposed to overlap the gate line GL. The first active line AL1 extends in the same direction as the gate line GL. The first active line AL1 is connected to the gate line GL through a contact hole. The first active line AL1 may not overlap the gate line extension parts GL_EP1, and GL_EP2.

A high power line VDDL, a low power line VSSL, a data lines DL1, DL2, DL3, and DL4 and a reference line RL are arranged in the second direction crossing the first direction, for example, in the vertical direction.

In the second direction, the fourth data line DL4, the third data line DL3, the reference line RL, the second data line DL2, and the first data line DL1 may be arranged in order, but are not limited thereto.

The data lines DL1, DL2, DL3, and DL4 supply a data signal to each of the sub-pixels SP1, SP2, and SP3 SP4.

The high power line VDDL may overlap the second data line DL2 and the reference line RL, and the low power line VSSL may overlap the third data line DL3 and the fourth data line DL4, but is not limited thereto.

The high power line VDDL may be connected to a high power line connection part VDDL_CP. The high power line connection part VDDL_CP is connected to the high power line VDDL through a contact hole and extends from the high power line VDDL in the first direction. The high power source VDD may be supplied to the plurality of sub-pixels SP1, SP2, SP3, and SP4, for example, the first to third sub-pixels, through the high power line connection part VDDL_CP.

In addition, a high power line extension part VDDL_EP may extend from the high power line VDDL. The high power line extension part VDDL_EP may extend from the high power line VDDL to the fourth sub-pixel in the first direction. The high power VDD may be supplied to the fourth sub-pixel through the high power line extension part VDDL_EP.

The data lines DL1, DL2, DL3, and DL4 and the reference line RL may be formed of the same material on the same layer. The data lines DL1, DL2, DL3, and DL4 and the reference line RL may be positioned below the gate line GL with an insulating layer therebetween.

The high power line VDDL and the low power line VSSL may be made of the same material on the same layer. The high power line VDDL and the low power line VSSL may be positioned above the gate line GL with an insulating layer therebetween.

The high power line connection part VDDL_CP may be formed of the same material on the same layer as the gate line GL. The high power line extension part VDDL_EP may be integrally formed with the high power line VDDL.

The high power line VDDL, the low power line VSSL, the data lines DL1, DL2, DL3, and DL4, and the reference line RL intersect the first active line AL1 while overlapping the first active line AL1.

A plurality of contact holes for connecting the first active line AL1 to the gate line GL may be disposed not to overlap the high power line VDDL, the low power line VSSL, the data lines DL1, DL2, DL3, and DL4, and the reference line RL.

A first sub-pixel SP1 may be disposed above one side of the gate line GL while partially overlapping the gate line GL, and a second sub-pixel SP2 and a third sub-pixel SP3 may be sequentially disposed below the first sub-pixel SP1. In addition, a fourth sub-pixel SP4 may be disposed above the other side of the gate line GL while partially overlapping the gate line GL. The fourth sub-pixel SP4 may face the first sub-pixel SP1.

The first to third sub-pixels SP1, SP2, and SP3 may overlap the high power line VDDL, the low power line VSSL, the data lines DL1, DL2, DL3, and DL4, and the reference line RL.

The fourth sub-pixel SP4 may not overlap the high power line VDDL, the low power line VSSL, the data lines DL1, DL2, DL3, and DL4, and the reference line RL.

Each of the sub-pixels SP1, SP2, SP3, and SP4 may include a light emitting area, a line area, and a circuit area. In this case, the light emitting area may overlap at least a portion of the line area and the circuit area, and in this case, the electroluminescent display device may be configured in a top emission type.

In addition, a right area of the second and third sub-pixels SP2 and SP3 and a lower area of the fourth sub-pixel SP4 may be formed of a transmissive area through which external light may transmit.

The fourth data line DL4 and the third data line DL3 may be disposed adjacent to each other without other wirings being disposed therebetween. The third data line DL3 and the reference line RL may be disposed adjacent to each other without other wirings being disposed therebetween. The reference line RL and the second data line DL2 may be disposed adjacent to each other without other wirings being disposed therebetween. The second data line DL2 and the first data line DL1 may be disposed adjacent to each other without other wirings being disposed therebetween.

According to another embodiment of the present disclosure, the data lines DL1, DL2, DL3, and DL4 and the reference line RL are disposed adjacent to each other, and the high power line VDDL and the low power line VSSL are disposed adjacent to each other to overlap the data lines DL1, DL2, DL3, and DL4 and the reference line RL.

Thus, according to another embodiment of the present disclosure, various lines are adjacent to each other to form the line area, and the circuit area including a plurality of thin film transistors T1, T2, and T3 is arranged to be adjacent to the line area, thereby reducing the total size of the line area and the circuit area. Accordingly, a resolution can be increased by reducing a size of the light emitting area, and a size of the transmissive area can also be increased.

A switching thin film transistor T1, a driving thin film transistor T2, and a sensing thin film transistor T3 are disposed in the circuit area of each of the four sub-pixels SP1, SP2, SP3, and SP4.

The switching thin film transistor T1 includes a first gate electrode G1, a first source electrode S1, a first drain electrode D1, and a first active layer A1.

The first gate electrode G1 of the second sub-pixel SP2 may include a part of the gate line GL, the first gate electrode G1 of the first sub-pixel SP1 and the third sub-pixel SP3 may include a part of the first gate line extension part GL_EP1, more specifically a part of the second portion of the first gate line extension part GL_EP1 extending in the horizontal direction, and the first gate electrode G1 of the fourth sub-pixel SP4 may include a portion of the second gate line extension part GL_EP4.

The first source electrode S1 may be connected to the data lines DL1, DL2, DL3, and DL4 through a contact hole, and may be connected to one end of the first active layer A1 through a contact hole.

The first drain electrode D1 may be disposed on the same layer as the first source electrode S1, and may be connected to the other end of the first active layer A1 through a contact hole.

The first source electrode S1 and the first drain electrode D1 may be formed of the same material as the first gate electrode G1, but are not limited thereto.

The first active layer A1 may be connected to the first source electrode S1 and the first drain electrode D1 through a contact hole, respectively, to function as an electron moving channel.

The driving thin film transistor T2 includes a second gate electrode G2, a second source electrode S2, a second drain electrode D2, and a second active layer A2.

The second gate electrode G2 may be connected to the first drain electrode D1 of the switching thin film transistor T1. The second gate electrode G2 may be integrally formed with the first drain electrode D1, but is not limited thereto.

The second source electrode S2 may be connected to one end of the second active layer A2 through a contact hole. The second source electrode S2 may be connected to a light blocking layer LS thereunder through a contact hole.

The light blocking layer LS may be formed of the same material in the same layer as the data lines DL1, DL2, DL3, and DL4, and the reference line RL. The light blocking layer LS may overlap the second active layer A2 to block external light from being incident on the second active layer A2. In addition, the light blocking layer LS may function as a capacitor electrode. Specifically, the light blocking layer LS and the second gate electrode G2 may overlap each other with an insulating layer therebetween, so that a capacitor may be formed by the light blocking layer LS and the second gate electrode G2.

The second source electrode S2 may be connected to two connection electrodes CE1 and CE2 through contact holes. The two connection electrodes CE1 and CE2 may be formed of the same material on the same layer as the high power line VDDL and the low power line VSSL.

Like the first to third sub-pixels SP1, SP2, and SP3, a first connection electrode CE1 may be connected to the second source electrode S2 through a contact hole, and a second connection electrode CE1 may be branched from the first connection electrode CE1. In addition, like the fourth sub-pixel SP4, each of the first connection electrode CE1 and the second connection electrode CE2 may be connected to the second source electrode S2 through a contact hole.

The first connection electrode CE1 may be connected to a first sub-electrode 200a that functions as one anode through a contact hole, and the second connection electrode CE2 may be connected to a second sub-electrode 200b that functions as the other anode through a contact hole. Accordingly, the first electrodes 200a and 200b of one sub-pixel may be formed of two sub-electrodes 200a and 200b that are spaced apart from each other. The two sub-electrodes 200a and 200b may be driven at the same time, or only one sub-electrode 200a and 200b may be driven by a repair process for solving defects.

The second drain electrode D2 may be connected to the other end of the second active layer A2 through a contact hole.

Like the first to third subpixels SP1, SP2, and SP3, the second drain electrode D2 may be connected to the high power line VDDL through a high power line connection part VDDL_CP. The high power line connection part VDDL_CP is connected to the high power line VDDL through a contact hole. The high power line connection part VDDL_CP may be connected to the second drain electrode D2 of the first to third subpixels SP1, SP2, and SP3 while extending in the first direction. The high power line connection part VDDL_CP and the second drain electrode D2 may be integrally formed.

Like the fourth sub-pixel SP4, the second drain electrode D2 may be connected to the high power line VDDL through a high power line extension part VDDL_EP. The high power line extension part VDDL_EP may be integrally formed with the high power line VDDL. The high power line extension part VDDL_EP may be connected to the second drain electrode D2 through a contact hole.

The second source electrode S2 and the second drain electrode D2 may be formed of the same material as the second gate electrode G2, but are not limited thereto.

In some cases, a configuration connected to the high power line VDDL through the high power line connection part VDDL_CP or the high power line extension part VDDL_EP may function as a source electrode, and a configuration connected to the first electrodes 200a and 200b through the connection electrodes CE1 and CE2 may function as a drain electrode.

The second active layer A2 may be connected to the second source electrode S2 and the second drain electrode D2 through a contact hole, respectively, to function as an electron moving channel. The second active layer A2 may be formed of the same material on the same layer as the first active layer A1.

The sensing thin film transistor T3 includes a third gate electrode G3, a third source electrode S3, a third drain electrode D3, and a third active layer A3.

The third gate electrode G3 of the second sub-pixel SP2 may include a portion of the gate line GL, the third gate electrode G3 of the first sub-pixel SP1 and the third sub-pixel SP3 may include a portion of the first gate line extension part GL_EP1, specifically a portion of the second portion of the first gate line extension part GL_EP1, and the third gate electrode G3 of the fourth sub-pixel SP4 may include a portion of the second gate line extension part GL_EP4.

The third source electrode S3 may be integrally formed with the second source electrode S2 of the driving thin film transistor T2. Alternatively, the third source electrode S3 may be connected to the light blocking layer LS through a contact hole, and thus may be electrically connected to the second source electrode S2 of the driving thin film transistor T2 through the light blocking layer LS.

The third source electrode S3 may be connected to one end of the third active layer A3 through a contact hole.

The third drain electrode D3 may be formed of the same material on the same layer as the third source electrode S3, and may be connected to the other end of the third active layer A3 through a contact hole. In addition, the third drain electrode D3 may be connected to the reference line RL through a contact hole. One third drain electrode D3 may be shared in the first sub-pixel SP1, the second sub-pixel SP2, and the fourth sub-pixel SP4, and a separate third drain electrode D3 that is not shared with the other sub-pixels SP1, SP2, and SP4 may be disposed in the third sub-pixel SP3.

The third active layer A3 may be connected to the third source electrode S3 and the third drain electrode D3 through a contact hole, respectively, to function as an electron moving channel. The third active layer A3 may be formed of the same material on the same layer as the first active layer A1.

According to another embodiment of the present disclosure, the thin film transistors T1, T2, and T3 may be formed in the first to third sub-pixels SP1, SP2, and SP3 at the highest density possible. Accordingly, a size of the circuit area may be minimized. In addition, a resolution may be improved by reducing sizes of the first to third sub-pixels SP1, SP2, and SP3.

For example, according to another embodiment of the present disclosure, since the thin film transistors T1, T2, and T3 are formed in a high density in the plurality of sub-pixels SP1, SP2, and SP3, at least a portion of the thin film transistors T1, T2, and T3 of one sub-pixel may be formed to overlap the other sub-pixel SP1, SP2, and SP3 areas adjacent thereto.

For example, at least a portion of the switching thin film transistor T1 of the second sub-pixel SP2 may be formed to overlap the first sub-pixel SP1. Alternatively, at least a portion of the sensing thin film transistor T3 of the second sub-pixel SP2 may be formed to overlap the first sub-pixel SP1.

Alternatively, at least a portion of the driving thin film transistor T2 of the third sub-pixel SP3 may be formed to overlap an area of the second sub-pixel SP2. Alternatively, at least a portion of the driving thin film transistor T2 of the first sub-pixel SP1 may be formed to overlap an area of the third sub-pixel SP3.

On the other hand, when at least a portion of one sub-pixel driving thin film transistor T2 overlaps with another sub-pixel area adjacent thereto, a parasitic capacitance is generated between the driving thin film transistor T2 of one sub-pixel and the first electrodes 200a and 200b of the other sub-pixel, for example, the second sub-electrode 200b.

For example, when at least a portion of the driving thin film transistor T2 of the third sub-pixel SP3 overlaps an area of the second sub-pixel SP2, a parasitic capacitance may be generated between the driving thin film transistor T2 of the third sub-pixel SP3 and the second sub-electrode 200b of the second sub-pixel SP2. Accordingly, a gate voltage of the driving thin film transistor T2 of the third sub-pixel SP3 increases, and when the third sub-pixel SP3 emits light, a luminance increases, resulting in a gray scale defect.

Accordingly, according to another embodiment of the present disclosure, in order to prevent the parasitic capacitance, shielding layers SL1 and SL2 may be additionally disposed in an area in which at least a portion of the driving thin film transistor T2 of the one sub-pixel overlaps another sub-pixel area adjacent thereto. For example, a first shielding layer SL1 may be additionally disposed on at least a portion of the driving thin film transistor T2 of the third sub-pixel SP3 overlapping an area of the second sub-pixel SP2, and a second shielding layer SL2 may be additionally disposed on at least a portion of the driving thin film transistor T2 of the first sub-pixel SP1 overlapping an area of the third sub-pixel SP3.

The shielding layers SL1 and SL2 may be patterned simultaneously with the same material on the same layer as the connection electrodes CE1 and CE2. However, the present disclosure is not limited thereto, and the shielding layers SL1 and SL2 may be disposed above the connection electrodes CE1 and CE2.

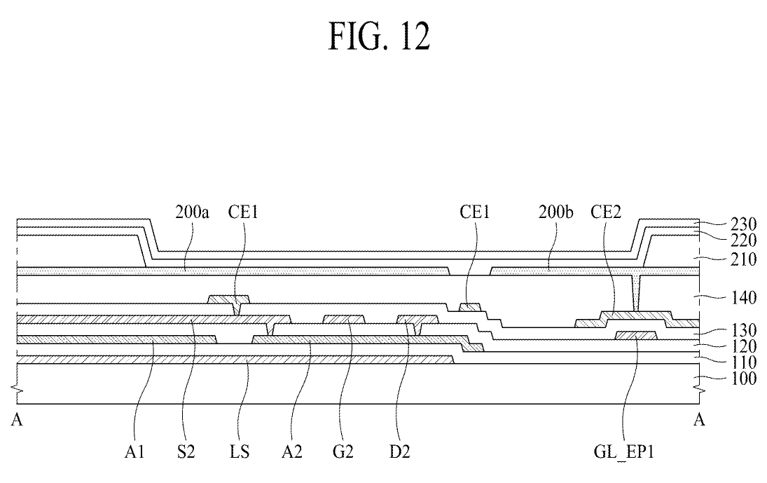

FIG. 12 is a cross-sectional view of an electroluminescent display device according to another embodiment of the present disclosure, which corresponds to a cross-section taken along line A-A of FIG. 11.

As shown in FIG. 12, a light blocking layer LS is disposed on the substrate 100.

The substrate 100 may be made of glass or plastic, but is not limited thereto. The electroluminescent display device according to an embodiment of the present disclosure may be made of a bottom emission type, and accordingly, a transparent material may be used as a material of the substrate 100.

A first insulating layer 110 is disposed on the light blocking layer LS. The first insulating layer 110 may be formed of an inorganic insulating material.

A second active layer A2 and a first active layer A1 are disposed on the first insulating layer 110.

At least a portion of the second active layer A2 and the first active layer A1 may overlap the light blocking layer LS, so that light entering under the substrate 100 may be blocked by the light blocking layer LS to prevent the light from entering at least a portion of the second active layer A2 and the first active layer A1.

A second insulating layer 120 is disposed on the second active layer A2 and the first active layer A1.

The second insulating layer 120 may be disposed on the entire surface of the substrate 100 except for a contact hole area. However, the present disclosure is not limited thereto, and the second insulating layer 120 may be formed in the same pattern as the second source electrode S2, the second gate electrode G2, the second drain electrode D2, and the first gate line extension part GL_EP except for the contact hole area.

The second insulating layer 120 may be made of an inorganic insulating material.

A second source electrode S2, a second gate electrode G2, a second drain electrode D2, and a first gate line extension portion GL_EP are disposed on the second insulating layer 120 to be spaced apart from each other.

The second source electrode S2 overlaps the second active layer A2, and is connected to one end of the second active layer A2 through a contact hole disposed in the second insulating layer 120. The second source electrode S2 may overlap the first active layer A1, but is not connected to the first active layer A1.

The second gate electrode G2 overlaps the second active layer A2, and is disposed in an area between the second drain electrode D2 and the second source electrode S2.

The second drain electrode D2 overlaps the second active layer A2, and is connected to the other end of the second active layer A2 through a contact hole disposed in the second insulating layer 120.

The first gate line extension part GL_EP may be disposed not to overlap the first active layer A1 and the second active layer A2.

The second source electrode S2, the second gate electrode G2, the second drain electrode D2, and the first gate line extension part GL_EP may be patterned using the same material through the same process in the same layer.

A third insulating layer 130 may be disposed on the second source electrode S2, the second gate electrode G2, the second drain electrode D2, and the first gate line extension part GL_EP.

The third insulating layer 130 may be disposed on an entire surface of the substrate 100 except for a contact hole area. The third insulating layer 130 may be made of an inorganic insulating material.

A first connection electrode CE1 and a second connection electrode CE2 are disposed on the third insulation layer 130.

The first connection electrode CE1 and the second connection electrode CE2 may be patterned using the same material through the same process in the same layer.

The first connection electrode CE1 may be connected to the second source electrode S2 through a contact hole disposed in the third insulating layer 130.

The second connection electrode CE2 may overlap the first gate line extension part GL_EP.

A fourth insulation layer 140 is disposed on the first connection electrode CE1 and the second connection electrode CE2.

The fourth insulating layer 140 may include a planarization layer made of an organic insulating material. The fourth insulating layer 140 may be formed of a plurality of insulating layers, and for example, may have a two-layer structure including a passivation layer made of an inorganic material and a planarization layer made of an organic material.

A first electrode 200a and 200b and a bank 210 are disposed on the fourth insulation layer 140.

Each of the first electrodes 200a and 200b may include a first sub-electrode 200a and a second sub-electrode 200b that are spaced apart from each other while functioning as an anode. The second sub-electrode 200b is connected to the second connection electrode CE2 through a contact hole disposed on the fourth insulation layer 140.

The first electrodes 200a and 200b may include reflective electrodes. Accordingly, light emitted from the light emitting layer 220 may be reflected from the first electrodes 200a and 200b and may proceed in an upward direction.

A bank 210 is disposed on the first electrodes 200a and 200b, a light emitting layer 220 is disposed on the bank 210, and a second electrode 230 is disposed on the light emitting layer 220.

The bank 210, the light emitting layer 220, and the second electrode 230 are the same as those in the above-described embodiment.

In addition, as in the above-described embodiment, an encapsulation layer, a color filter, and a touch sensor may be additionally configured on the second electrode 230.

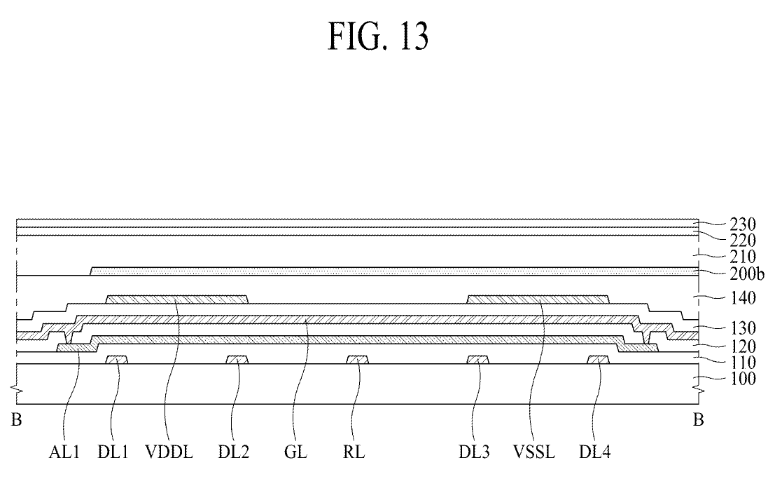

FIG. 13 is a cross-sectional view of an electroluminescent display device according to another embodiment of the present disclosure, which corresponds to a cross-section taken along line B-B of FIG. 11.

As shown in FIG. 13, a data line DL1, DL2, DL3, DL4, and a reference line RL are disposed on the substrate 100.

A first insulating layer 110 is disposed on the data lines DL1, DL2, DL3, and DL4, and the reference line RL, and a first active lines AL1 are disposed on the first insulating layer 110.

The first active line AL1 may overlap an entire area of data lines DL1, DL2, DL3, and DL4 and the reference line RL and have a width wider than the entire width of the data lines DL1, DL2, DL3, and DL4 and the reference line RL. For example, a left end of the first active line AL1 is located on a left side of a left end of the first data line DL1, and a right end of the first active line AL1 is located on a right side of a right end of the fourth data line DL4.

A second insulating layer 120 is disposed on the first active lines AL1 and a gate line GL is disposed on the second insulating layer 120.

The gate line GL is connected to the first active line AL1 through a contact hole disposed in the second insulating layer 120. Specifically, the gate line GL is connected to one side and the other side of the first active line AL1 through a contact hole disposed in the second insulating layer 120. In this case, a contact hole corresponding to one side of the first active line AL1 is located at the left side of the left end of the first data line DL1, and a contact hole corresponding to the other side of the first active line AL1 may be located at the right side of the right end of the fourth data line DL4.

Although not shown in FIG. 10, a short defect occurs between the data lines D1, DL2, DL3, and DL4 and the first active line AL1 by forming particles between the data lines D1, DL2, DL3, and DL4 and the first active line AL1 disposed on the data lines D1, DL2, DL3, and DL4. In this case, by irradiating the laser from the lower side of the substrate 100 to cut one side and the other side of the first active line AL1, the electrical connection between a portion of the first active line AL1 in an area where the short defect occurs and the gate line GL may be blocked, and accordingly, the short defect may be repaired between the data lines DL1, DL2, DL3, and DL4 and the gate line GL.

In addition, when a short defect occurs between the reference line RL and the first active line AL1 by forming particles between the reference line RL, and the first active line AL1, the short defect may be repaired by cutting one side and the other side of the first active line AL1 in the short defect area.

A third insulating layer 130 is disposed on the gate line GL, and a high power line VDDL and a low power line VSSL are disposed on the third insulating layer 130.

A fourth insulating layer 140 is disposed on the high power line VDDL and the low power line VSSL, a first electrode 200b is disposed on the fourth insulating layer 140, a bank 210 is disposed on the first electrode 200b, a light emitting layer 220 is disposed on the bank 210, and a second electrode 230 is disposed on the light emitting layer 220.

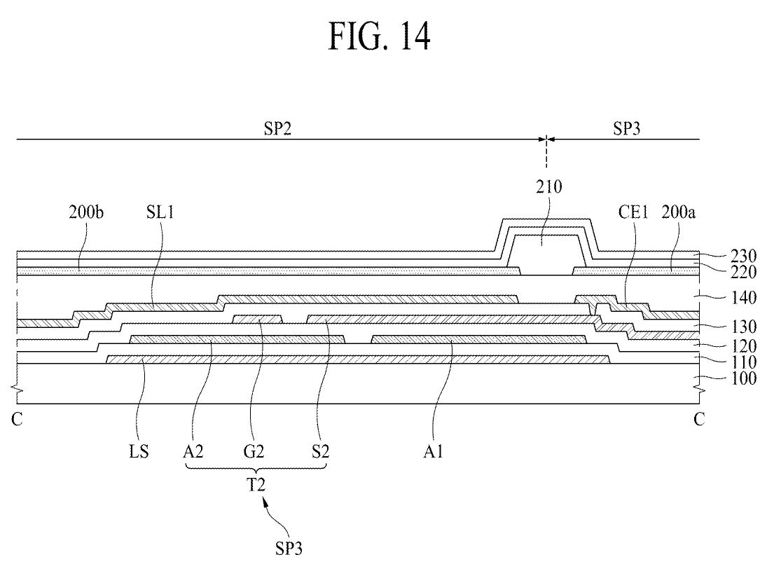

FIG. 14 is a cross-sectional view of an electroluminescent display device according to another embodiment of the present disclosure, which corresponds to a cross section taken along line C-C of FIG. 11.

As can be seen from FIG. 14, a light blocking layer LS is disposed on the substrate 100, and a first insulating layer 110 is disposed on the light blocking layer LS.

A second active layer A2 and a first active layer A1 are disposed on the first insulating layer 110, and a second insulating layer 120 is disposed on the second active layer A2 and the first active layer A1.

A second gate electrode G2 and a second source electrode S2 may be disposed on the second insulating layer 120, and a third insulating layer 130 may be disposed on the second gate electrode G2 and the second source electrode S2.

A first shielding layer SL1 and a first connection electrode CE1 are disposed on the third insulation layer 130.

The second active layer A2, the second gate electrode G2, and the second source electrode S2 constitute the driving thin film transistor T2 of the third sub-pixel SP3, and at least a portion of the second active layer A2, the second gate electrode G2, and the second source electrode S2 is disposed in an area of the second sub-pixel SP2.

That is, at least a portion of the driving thin film transistor T2 of the third sub-pixel SP3 is disposed in the area of the second sub-pixel SP2.

The first shielding layer SL1 may overlap at least a portion of the driving thin film transistor T2 of the third sub-pixel SP3 disposed in the area of the second sub-pixel SP2.

The first shielding layer SL1 is disposed between at least a portion of the driving thin film transistor T2 of the third sub-pixel SP3 and the first electrode 200b of the second sub-pixel SP2, thereby preventing parasitic capacitance between the driving thin film transistor T2 of the third sub-pixel SP3 and the first electrode 200b of the second sub-pixel SP2, and specifically the second sub-electrode 200b.

For example, the first shielding layer SL1 may overlap the second active layer A2, the second gate electrode G2, and the second source electrode S2 of the driving thin film transistor T2 of the third sub-pixel SP3 disposed in the area of the second sub-pixel SP2. Although not shown, the first shielding layer SL1 may overlap the second drain electrode D2 of the driving thin film transistor T2 of the third sub-pixel SP3 disposed in the area of the second sub-pixel SP2.

The first connection electrode CE1 may be connected to the second source electrode S2 through a contact hole disposed in the third insulating layer 130.

A fourth insulating layer 140 is disposed on the first shielding layer SL1 and the first connection electrode CE1, and the second sub-electrode 200b of the second sub-pixel SP2 and the first sub-electrode 200a of the third sub-pixel SP3 are disposed on the fourth insulating layer 140.

A bank 210 is disposed between the second sub-electrode 200b of the second sub-pixel SP2 and the first sub-electrode 200a of the third sub-pixel SP3.

A light emitting layer 220 is disposed on the sub-electrodes 200a and 200b and the bank 210, and a second electrode 230 is disposed on the light emitting layer 220.

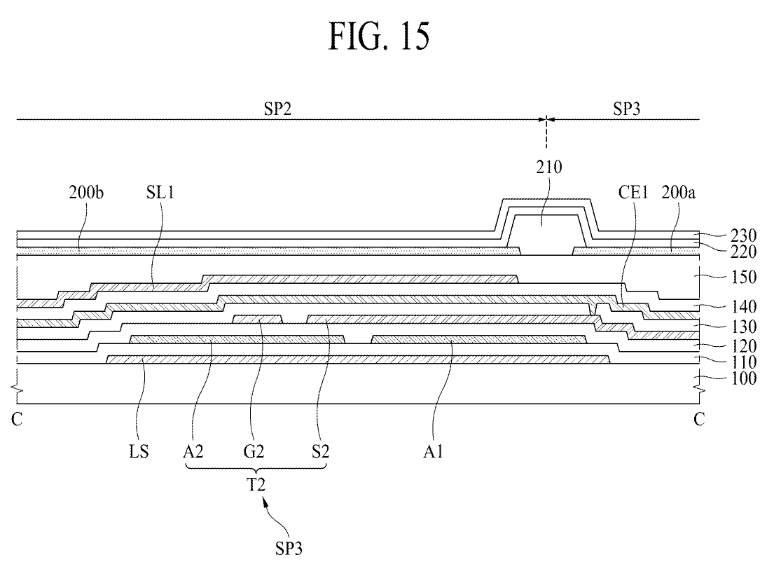

FIG. 15 is a cross-sectional view of an electroluminescent display device according to another embodiment of the present disclosure, which corresponds to a cross section taken along line C-C of FIG. 11. FIG. 15 is different from FIG. 14 described above in that the configurations of the first shielding layer SL1 and the first connection electrode CE1 are changed. Accordingly, the same reference numerals are assigned to the same configurations, and hereinafter, only different configurations will be described.

As shown in FIG. 15, a first connection electrode CE1 is disposed on a third insulation layer 130, a fourth insulating layer 140 is disposed on the first connection electrode CE1, a first shielding layer SL1 is disposed on the fourth insulating layer 140, a fifth insulating layer 150 is disposed on the first shielding layer SL1, and a first electrode 200a and 200b are disposed on the fifth insulating layer 150.

The first connection electrode CE1 extends from the third sub-pixel SP3 to the second sub-pixel SP2. The first connection electrode CE1 may overlap at least a portion of the driving thin film transistor T2 of the third sub-pixel SP3 disposed in an area of the second sub-pixel SP2.

For example, the first connection electrode CE1 may overlap the second active layer A2, the second gate electrode G2, and the second source electrode S2 of the driving thin film transistor T2 of the third sub-pixel SP3 disposed in the area of the second sub-pixel SP2. Although not shown, the first connection electrode CE1 may overlap the second drain electrode D2 of the driving thin film transistor T2 of the third sub-pixel SP3 disposed in the area of the second sub-pixel SP2.

Accordingly, since the first connection electrode CE1 is disposed between at least a portion of the driving thin film transistor T2 of the third sub-pixel SP3 and the first electrode 200b of the second sub-pixel SP2, a parasitic capacitance between the driving thin film transistor T2 of the third sub-pixel SP3 and the first electrode 200b of the second sub-pixel SP2 may be prevented. That is, the first connection electrode CE1 may function as a separate shielding layer.

In addition, the first shielding layer SL1 is disposed in the second sub-pixel SP2. The first shielding layer SL1 is disposed between a portion of the first connection electrode CE1 extending to the second sub-pixel SP2 and the first electrode 200b of the second sub-pixel SP2, thereby preventing a parasitic capacitance between the first connection electrode CE1 and the first electrode 200b of the second sub-pixel SP2.

Although the electroluminescent display device has been described above, the configuration of the active lines AL1 and AL2 for preventing a short defect according to the present disclosure may be applied to various display devices.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate;
a gate line on the substrate, the gate line extending in a first direction;
at least one signal line on the substrate, the at least one signal line extending in a second direction transverse to the first direction to cross the gate line;
an active line disposed between the gate line and the at least one signal line and overlapping the gate line and the at least one signal line, respectively; and
a contact hole,
wherein the active line extends in a same direction as the gate line, and is electrically connected to the gate line through the contact hole.

2. The display device of claim 1, further comprising a first insulating layer disposed between the active line and the at least one signal line, and a second insulating layer disposed between the active line and the gate line,
wherein the active line is disposed above the at least one signal line and below the gate line, and
wherein the gate line is connected to the active line through the contact hole disposed in the second insulating layer.

3. The display device of claim 1, wherein the at least one signal line is selected from a data line, a reference line, and a power line.

4. The display device of claim 1, wherein the at least one signal line includes a plurality of lines, and the active line intersects the plurality of lines.

5. The display device of claim 4, wherein the plurality of lines include a first data line and a second data line disposed adjacent to each other.

6. The display device of claim 4, wherein the plurality of lines includes:
a first data line and a second data line disposed adjacent to each other;
a third data line and a fourth data line disposed adjacent to each other; and
a reference line spaced apart from the second data line with one sub-pixel interposed therebetween and spaced apart from the third data line with another sub-pixel interposed therebetween.

7. The display device of claim 4, wherein the plurality of lines includes a first data line, a second data line, a reference line, a third data line, and a fourth data line disposed adjacent to each other.

8. The display device of claim 1, wherein the contact hole does not overlap the at least one signal line.

9. The display device of claim 1, wherein the active line is connected to the gate line through two contact holes disposed at a first side and a second side of the gate line, respectively.

10. The display device of claim 1, wherein a portion of the active line that is disconnected is in contact with particles.

11. The display device of claim 1, further comprising at least one gate line extension part extending from the gate line in a direction different from the first direction,
wherein the active line does not overlap the gate line extension part.

12. A display device comprising:
a substrate;
a gate line on the substrate, the gate line extending in a first direction;
a gate line extension part including at least a portion extending in a direction different from the first direction in the gate line;
a first data line, a second data line, a third data line, a fourth data line, a reference line, and a power line arranged in a second direction transverse to the first direction to cross the gate line;
an active line crossing the first data line, the second data line, the third data line, the fourth data line, the reference line, and the power line and extending in the same direction as the gate line; and
a contact hole,
wherein the active line overlaps the gate line and is connected to the gate line through the contact hole.

13. The display device of claim 12, further comprising a first insulating layer disposed between the active line and the first to fourth data lines and a second insulating layer disposed between the active line and the gate line,
wherein the active line is disposed above the first to fourth data lines and below the gate line, and
wherein the gate line is connected to the active line through the contact hole disposed in the second insulating layer.

14. The display device of claim 13, further comprising a third insulating layer disposed between the power line and the gate line, and
wherein the power line is disposed above the gate line.

15. The display device of claim 12, wherein the first data line and the second data line are adjacent to each other, and the third data line and the fourth data line are adjacent to each other,
wherein a first sub-pixel and a second sub-pixel are disposed between the second data line and the reference line, and a third sub-pixel and a fourth sub-pixel are disposed between the third data line and the reference line, and
wherein a gate line extension part includes a first gate line extension part extended to the second sub-pixel, a second gate line extension part extended to the fourth sub-pixel, a third gate line extension part extended to the first sub-pixel, and a fourth gate line extension part extended to the third sub-pixel.

16. The display device of claim 15, wherein one end of the first gate line extension part and one end of the second gate line extension part are spaced apart from each other while facing each other with the reference line therebetween.

17. The display device of claim 15, further comprising a power line connection part connected to the power line,
wherein the first sub-pixel and the second sub-pixel are separated with the power line connection part therebetween, the third sub-pixel and the fourth sub-pixel are separated with the power line connection part therebetween, and
wherein the first sub-pixel faces the third sub-pixel with the reference line interposed therebetween, and the second sub-pixel faces the fourth sub-pixel with the reference line interposed therebetween.

18. The display device of claim 12, wherein the contact hole does not overlap the first data line, the second data line, the third data line, the fourth data line, the reference line, and the power line.

19. The display device of claim 12, wherein the active line is connected to the gate line through two contact holes disposed on opposite sides of the gate line, and
wherein one of the two contact holes is disposed on a side of the first data line, and the other of the two contact holes is disposed on a side the fourth data line.

20. The display device of claim 12, wherein the active line does not overlap the gate line extension part.
